(19) United States
(12) Patent Application Publication
(10) Pub. No.: US 2017/0352312 A1
(43) Pub. Date: Dec. 7, 2017

(54) DISPLAY DEVICE

(71) Applicant: JOLED INC., Tokyo (JP)

(72) Inventors: Kohei EBISUNO, Tokyo (JP); Shinya ONO, Osaka (JP); Hitoshi TSUGE, Tokyo (JP); Ichiro SATO, Tokyo (JP)

(73) Assignee: JOLED INC., Tokyo (JP)

(21) Appl. No.: 15/535,919

(22) PCT Filed: Dec. 9, 2015
(86) PCT No.: PCT/JP2015/006151

§ 371 Date: Jun. 14, 2017

(30) Foreign Application Priority Data
Dec. 18, 2014 (JP) 2014-256279

(51) Int. Cl. G09G 3/3233; H01L 27/32; G09G 3/20; H01L 51/52; H01L 51/50

(52) U.S. Cl. CPC G09G 3/3233; H01L 27/3211; G09G 3/2074; H01L 27/322; G09G 2300/0452; G09G 2320/0233; G09G 2300/0842; H01L 51/5012; H01L 51/5275

(57) ABSTRACT

An organic EL display includes: a sub-pixel and a sub-pixel arranged adjacent to each other and each including a driving transistor; and a power supply line for supplying a power supply voltage to the driving transistor of the sub-pixel and the driving transistor of the sub-pixel, the power supply line being disposed at a boundary between the sub-pixel and the sub-pixel. The driving transistor of the sub-pixel and the driving transistor of the sub-pixel are oriented in a same direction.

### TECHNICAL FIELD

The present disclosure relates to a display device.

### BACKGROUND ART

A display device such as a liquid crystal display, an organic electroluminescence (EL) display, or a plasma display panel includes a plurality of pixels arranged in a matrix. In some display devices, each of the plurality of pixels includes a light-emitting element and a transistor.

### CITATION LIST

### Patent Literature

[PTL 1] Japanese Unexamined Patent Application Publication No. 2010-008654

[PTL 2] Japanese Patent No. 4240059

### SUMMARY OF INVENTION

### Technical Problem

Conventional display devices, however, have drawbacks that the degree of integration is not sufficiently increased and variations in the transistor characteristics between pixels are not sufficiently reduced. Such variations between pixels in the transistor characteristics or the pixel circuit input/output characteristics cause variations in the luminance, chrominance, etc., resulting in a problem of degradation of video quality.

The present disclosure provides a display device capable of increasing the degree of integration and reducing variations between pixels in the transistor characteristics or the pixel circuit input/output characteristics.

### Solution to Problem

A display device according to the present disclosure is a display device including: a first pixel and a second pixel arranged adjacent to each other and each including a driving transistor; and a power supply line for supplying a power supply voltage to the driving transistor of the first pixel and the driving transistor of the second pixel, the power supply line being disposed at a boundary between the first pixel and the second pixel. In this display device, the driving transistor of the first pixel and the driving transistor of the second pixel are oriented in a same direction.

### Advantageous Effects of Invention

The display device according to the present disclosure is capable of increasing the degree of integration and reducing variations between pixels in the transistor characteristics or the pixel circuit input/output characteristics.

### BRIEF DESCRIPTION OF DRAWINGS

FIG. 1 is an external view showing an example of an appearance of an organic EL display according to a comparative example or an embodiment.

FIG. 2 is a block diagram illustrating an example of a configuration of an organic EL panel according to a comparative example or an embodiment.

FIG. 3 is a circuit diagram illustrating an example of a configuration of a sub-pixel according to a comparative example or an embodiment.

FIG. 4 is a layout diagram illustrating an example of a layout pattern of sub-pixels according to Comparative Example 1.

FIG. 5 is a layout diagram illustrating an example of a layout pattern of sub-pixels according to Comparative Example 2.

FIG. 6 is a diagram illustrating an example of a configuration of a bottom-gate transistor according to a comparative example or an embodiment.

FIG. 7 is a plan view showing a difference in an overlapping area due to misalignment.

FIG. 8 is a diagram illustrating a relationship between tilt of a lens to be aligned and the resulting misalignment with a mask in a transistor fabrication process.

FIG. 9 is a diagram illustrating a relationship between tilt of a lens to be aligned and the resulting misalignment with a mask in a transistor fabrication process.

FIG. 10A is a graph showing a relationship between an amount of misalignment and a current flowing between a source and a drain of a transistor.

FIG. 10B is a graph showing a relationship between a drain-side parasitic capacitance and pixel circuit input/output characteristics.

FIG. 11 is a diagram Illustrating an example of streaks due to misalignment.

FIG. 12 is a layout diagram illustrating an example of a layout pattern of sub-pixels according to Comparative Example 1.

FIG. 13 is a layout diagram illustrating an example of a layout pattern of sub-pixels according to Comparative Example 2.

FIG. 14 is a layout diagram illustrating an example of a layout pattern of sub-pixels according to an embodiment.

FIG. 15 is a layout diagram illustrating an example of a layout pattern of sub-pixels according to Variation 1 of the embodiment.

FIG. 16 is a layout diagram illustrating an example of a layout pattern of sub-pixels according to Variation 2 of the embodiment.

FIG. 17 is a layout diagram illustrating an example of a layout pattern of sub-pixels according to Variation 3 of the embodiment.

FIG. 18 is a layout diagram illustrating an example of application of the embodiment and Variations 1 to 3.

FIG. 19 is a layout diagram illustrating an example of application of the embodiment and Variations 1 to 3.

FIG. 20 is a layout diagram illustrating an example of application of the embodiment and Variations 1 to 3.

FIG. 21 is a layout diagram illustrating an example of application of the embodiment and Variations 1 to 3.

### DESCRIPTION OF EMBODIMENTS

### [Details of Problem]

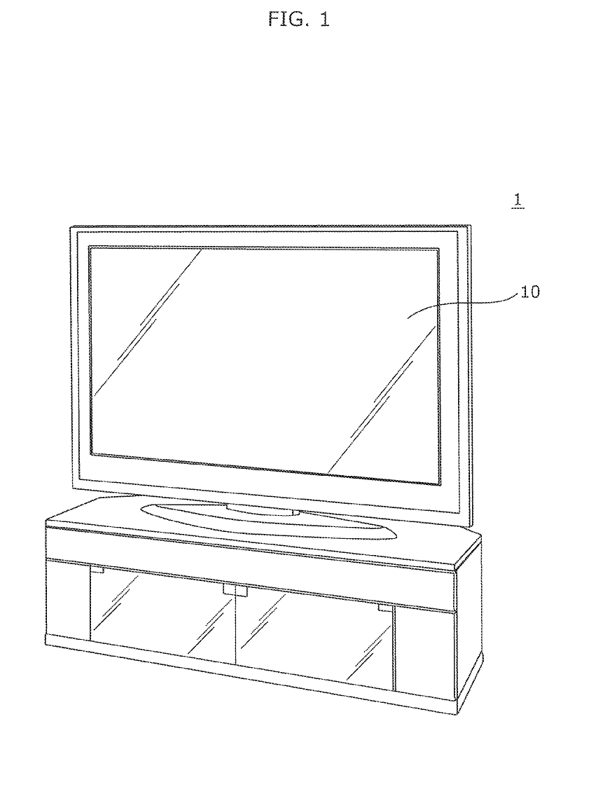

The details of the above-mentioned problem will be described with reference to FIG. 1 to FIG. 13.

### Comparative Example 1

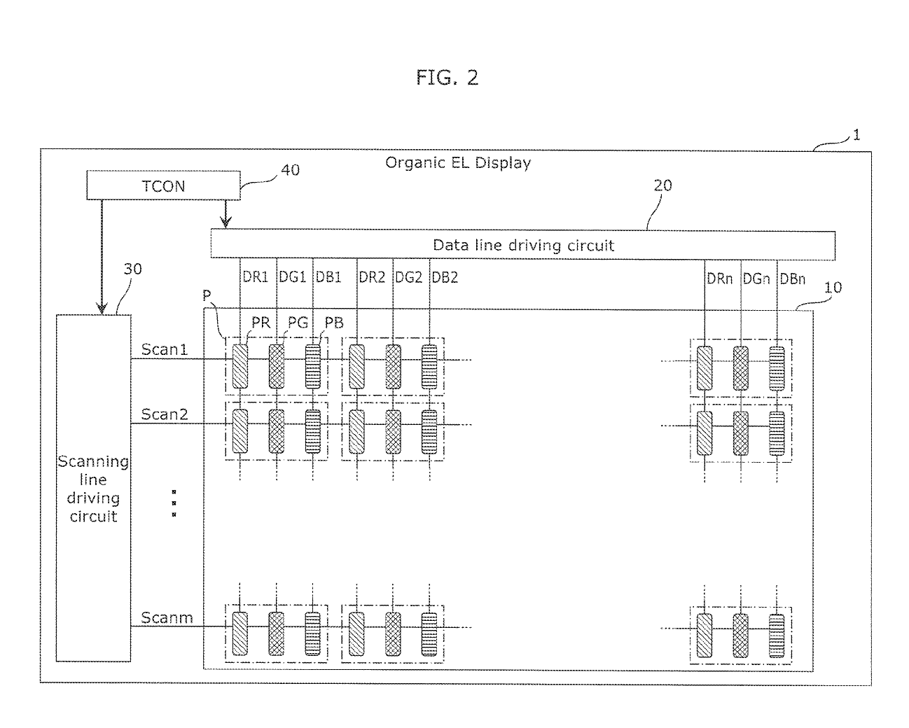

FIG. 1 is a diagram illustrating an example of an appearance of an organic EL display according to Comparative Example 1. FIG. 2 is a diagram illustrating an example of a configuration of the organic EL display according to Comparative Example 1.

As shown in FIG. 1 and FIG. 2, an organic EL display 1 includes an organic EL panel 10, a data line driving circuit 20, a scanning line driving circuit 30, and a timing controller (TCON) 40. It should be noted that the data line driving circuit 20, the scanning line driving circuit 30, and the TCON 40 are not directly related to the problem to be solved and thus will be described in the embodiment.

The organic EL panel 10 includes a plurality of pixels P that are arranged in a matrix. Each of the plurality of pixels P includes a sub-pixel PR that emits red (R) light, a sub-pixel PG that emits green (G) light, and a sub-pixel PB that emits blue (B) light.

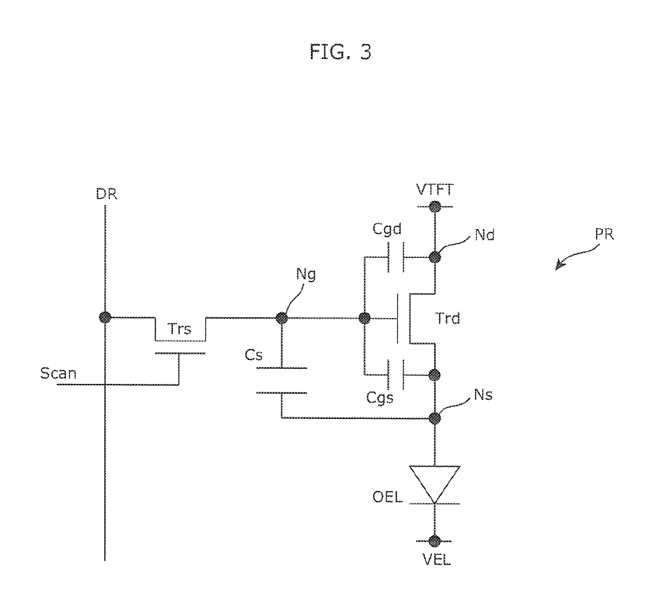

FIG. 3 is a circuit diagram illustrating an example of a configuration of a sub-pixel PR. As shown in FIG. 3, the sub-pixel PR includes an organic EL element OEL that emits light depending on a driving current, a capacitor Cs that accumulates electric charge corresponding to a voltage at a data signal line DR, a switching transistor Trs that switches between conduction and non-conduction between the data signal line DR and one end of the capacitor Cs, and a driving transistor Trd that supplies a driving current corresponding to the amount of electric charge accumulated in the capacitor Cs to the organic EL element OEL. Parasitic capacitance Cgd is formed between the gate and the drain of the driving transistor Trd, and parasitic capacitance Cgs is formed between the gate and the source thereof.

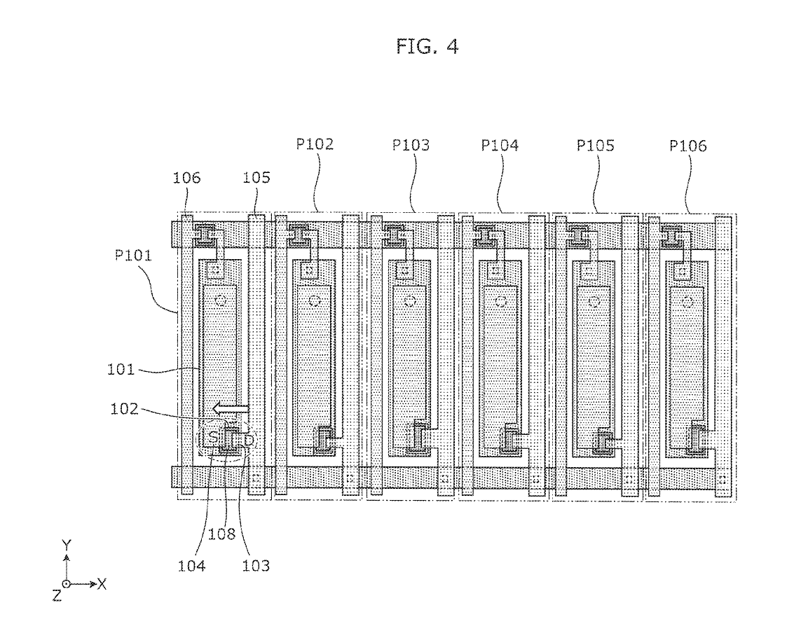

FIG. 4 is a diagram illustrating an example of a layout pattern in a portion of the organic EL panel according to Comparative Example 1. FIG. 4 shows six sub-pixels P101 to P106 that are respectively formed in six rectangular regions each of which is enclosed by a two-dot chain line. The sub-pixels P101 to P106 each correspond to one of a sub-pixel PR that emits red (R) light, a sub-pixel PG that emits green (G) light, and a sub-pixel PB that emits blue (B) light. The sub-pixels P101 to P106 are aligned in a row direction.

In each of the sub-pixels, a gate metal layer 101, a semiconductor layer 102, a channel protection film 108, a metal wiring layer composed of a drain metal layer 103 and a source metal layer 104, a power supply line 105, and a data signal line 106 are formed.

The gate metal layer 101 includes a gate electrode and a gate line connected to the gate electrode. The channel protection film 108 is a layer serving as an etching stopper and includes a channel region of the transistor in a top view. The drain metal layer 103 includes a drain electrode and a line connected to the drain electrode. The source metal layer 104 includes a source electrode and a line connected to the source electrode.

In each of the sub-pixels P101 to P106 shown in FIG. 4, the power supply line 105 is a long line extending in a column direction and is disposed on the right side of the rectangular region in FIG. 4. The data signal line 106 is a long line extending in the column direction and is disposed on the left side of the rectangular region in FIG. 4. The drain metal layer 103 is located on the right side of the semiconductor layer 102, and the source metal layer 104 is located on the left side of the semiconductor layer 102. Therefore, the direction of current flow between the source and the drain is a direction perpendicular to the power supply line 105, that is, a direction from right to left, as indicated by an arrow in FIG. 4.

### Comparative Example 2

There has been proposed an organic EL panel 10 in which a power supply line 105 is disposed at the boundary between two sub-pixels to reduce the area of each sub-pixel and increase the degree of integration (see, for example, Patent Literature (PTL) 1).

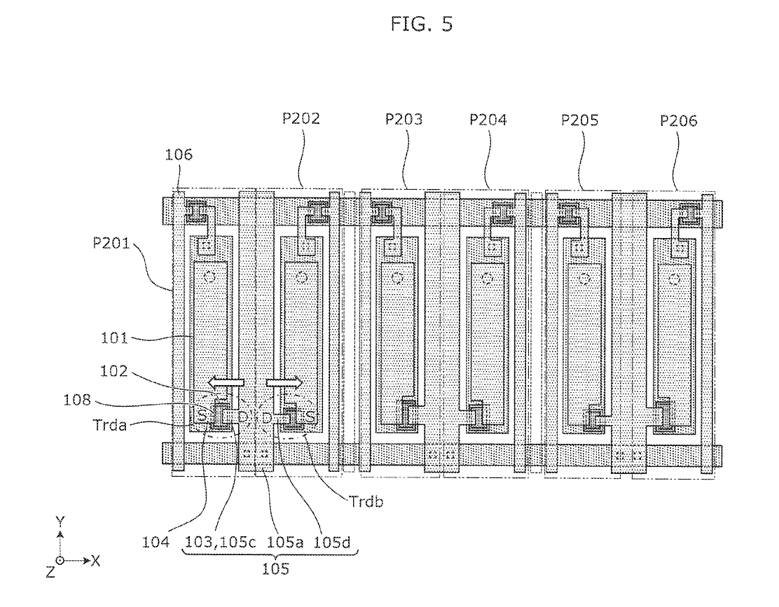

FIG. 5 is a diagram illustrating an example of a layout pattern of an organic EL panel 10 according to Comparative Example 2. The layout diagram shown in FIG. 5 includes a first sub-pixel P201 and a second sub-pixel P202 that are adjacent to each other in the row direction and a power supply line 105. The shape, size, and location of each component of the first sub-pixel P201 are symmetric to those of each component of the second sub-pixel P202 with respect to the boundary line between these two sub-pixels. The power supply line 105 includes: a first main power supply line 105a disposed on the boundary line between the first sub-pixel P201 and the second sub-pixel P202; a first sub power supply line 105c extending from the first main power supply line 105a to a drain electrode of a driving transistor Trda as a component of the first sub-pixel P201; and a second sub power supply line 105d extending from the first main power supply line 105a to a drain electrode of a driving transistor Trdb as a component of the second sub-pixel P202.

The sub-pixels P201, P203, and P205 in odd-numbered columns have the same configuration as the sub-pixel P101 in FIG. 4. The components of the sub-pixels P202, P204, and P206 In even-numbered columns are arranged axisymmetrically to those of the sub-pixel P101 in FIG. 4 with respect to the power supply line 105.

Therefore, in Comparative Example 2, the locations of the source electrode and the drain electrode in one of a pair of sub-pixels and those in the other of the pair of sub-pixels are symmetric (opposite) to each other. Therefore, in the sub-pixels P201, P203, and P205 in the odd-numbered columns, a source-drain current flows from right to left in FIG. 5. On the other hand, in the sub-pixels P202, P204, and P206 in the even-numbered columns, a source-drain current flows from left to right in FIG. 5.

### (Change in Amount of Current Flowing Between Source and Drain and Change in Pixel Circuit Input/Output Characteristics Due to Misalignment)

Here, misalignment may cause relative positional displacement between a source metal layer and a stack of a gate metal layer, a semiconductor layer, and a channel protection film and between a drain metal layer and the stack. Such misalignment results in a difference between the overlapping area of the channel protection film and the source metal layer and that of the channel protection film and the drain metal layer, or a difference between the overlapping area of the gate metal layer, the semiconductor layer, and the source metal layer and that of the gate metal layer, the semiconductor layer, and the drain metal layer, although it is ideal that these overlapping areas be equal to each other. Here in Comparative Example 2, the arrangement of the source electrode and the drain electrode in one of a pair of sub-pixels and that in the other of the pair of sub-pixels are opposite to each other. Therefore, in Comparative Example 2, in one of the pair of sub-pixels, the source-side overlapping area is larger than the drain-side overlapping area, while in the other of the pair of sub-pixels, the source-side overlapping area is smaller than the drain-side overlapping area. In other words, this difference in the overlapping area causes a difference in the transistor characteristics between the pair of sub-pixels and thus a difference in the magnitude of the parasitic capacitance depending on the characteristics of the transistor. Variations in the characteristics among a plurality of transistors due to misalignment and variations in the pixel circuit input/output characteristics due to variations in parasitic capacitance are described in more detail below.

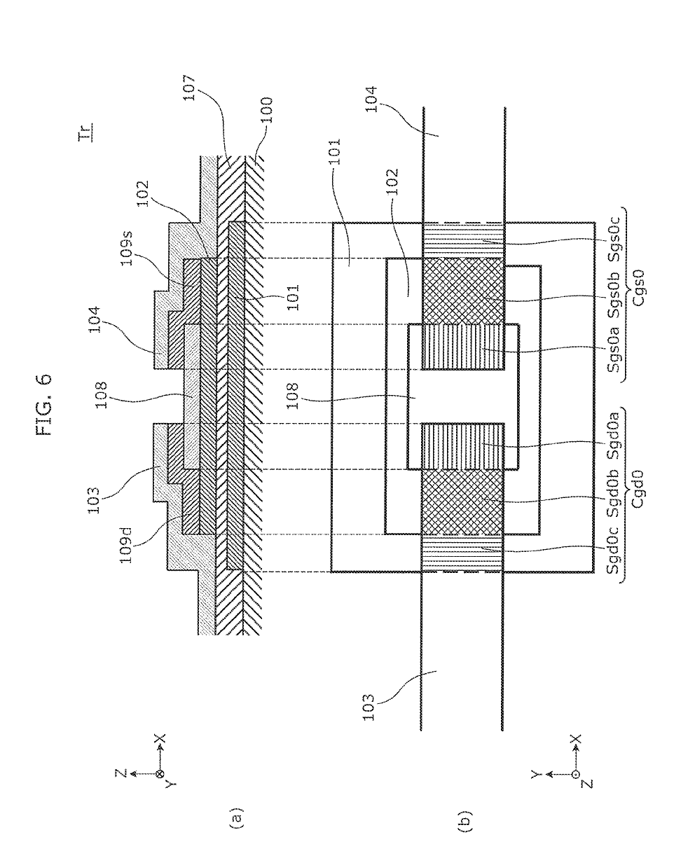

FIG. 6 is a diagram illustrating an example of a configuration of a bottom-gate type CES transistor Tr. It should be noted that, in FIG. 6, a plane parallel to an XY plane is parallel to a glass substrate 100, in other words, parallel to the surface of the organic EL panel 10. In FIG. 6, (a) is a cross-sectional view showing an example of the configuration of the transistor Tr, that is, a cross section of the transistor Tr, taken along a plane parallel to an XZ plane. In FIG. 6, (b) is a diagram illustrating a gate metal layer 101, a semiconductor layer 102, a channel protection film 108, a drain metal layer 103, and a source metal layer 104, among the components of the transistor Tr, that is, a top view of the organic EL panel 10, as seen from the positive side of the Z axis.

As shown in (a) and (b) of FIG. 6, the bottom-gate type CES transistor Tr includes a glass substrate 100, a gate metal layer 101, a gate insulating film 107, a semiconductor layer 102, a channel protection film 108, ohmic contact layers 109d and 109s, a drain metal layer 103, and a source metal layer 104.

The gate metal layer 101 is disposed on the glass substrate 100. The gate insulating film 107 is formed to partially cover the gate metal layer 101 and the glass substrate 100. The semiconductor layer 102 is formed on the gate Insulating film 107. As shown in (b) of FIG. 6, the lengths of the semiconductor layer 102 in the X axis and Y axis directions are respectively shorter than the lengths of the gate metal layer 101 in the X axis and Y axis directions, and thus the semiconductor layer 102 is disposed within the region of the gate metal layer 101 on the XY plane.

The channel protection film 108 is formed on a portion of the semiconductor layer 102. The ohmic contact layer 109d is formed between the drain metal layer 103 and the semiconductor layer 102 and between the drain metal layer 103 and the channel protection film 108. The ohmic contact layer 109s is formed between the source metal layer 104 and the semiconductor layer 102 and between the source metal layer 104 and the channel protection film 108. It should be noted that parasitic capacitance Cgs is formed in an overlapping region in which the gate metal layer 101 and the source metal layer 104 overlap one another, as seen from the positive side of the Z axis. The overlapping region in which the parasitic capacitance Cgs is formed consists of the following three regions. The first one of the three regions is an overlapping region Sgs0a in which the gate metal layer 101, the gate insulating film 107, the semiconductor layer 102, the channel protection film, the ohmic contact layer 109d, and the source metal layer 104 overlap one another. The second one of the three regions is an overlapping region Sgs0b in which the gate metal layer 101, the gate insulating film 107, the semiconductor layer 102, the ohmic contact layer 109d, and the source metal layer 104 overlap one another. The third one of the three regions is an overlapping region Sgs0c in which the gate metal layer 101, the gate insulating film 107, and the source metal layer 104 overlap one another. The sum of the capacitances in these three regions is referred to as parasitic capacitance Cgs. On the drain side, parasitic capacitance Cgd is formed in the same manner as on the source side. That is, the parasitic capacitance Cgd is formed in an overlapping region in which the gate metal layer 101 and the drain metal layer 103 overlap one another, as seen from the positive side of the Z axis.

### (Change in Amount of Current Flowing Between Source and Drain Due to Misalignment)

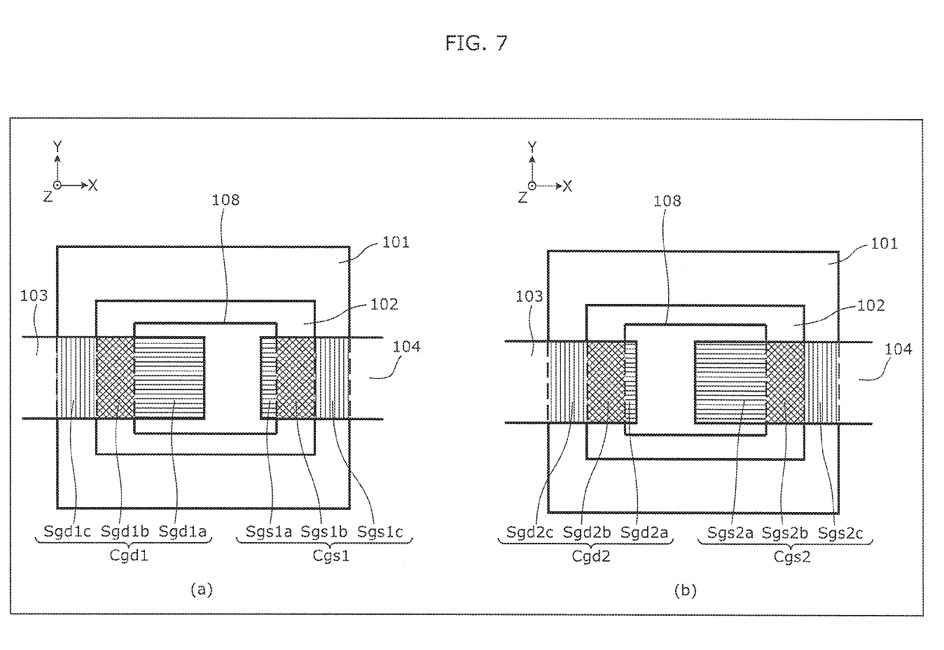

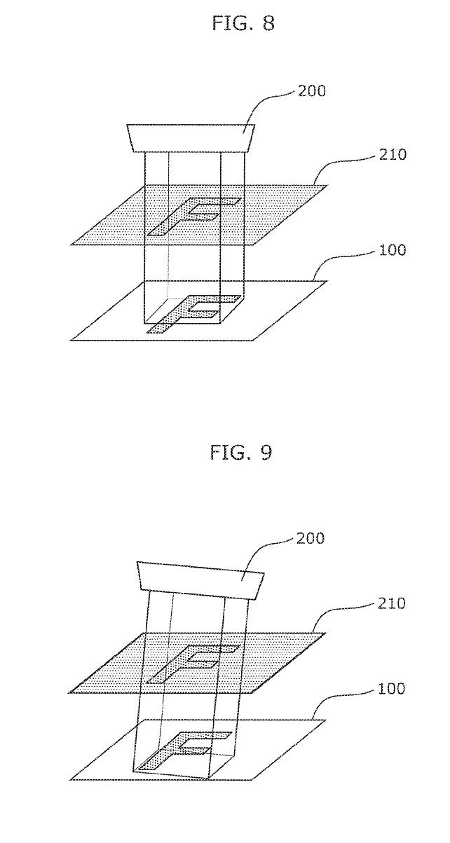

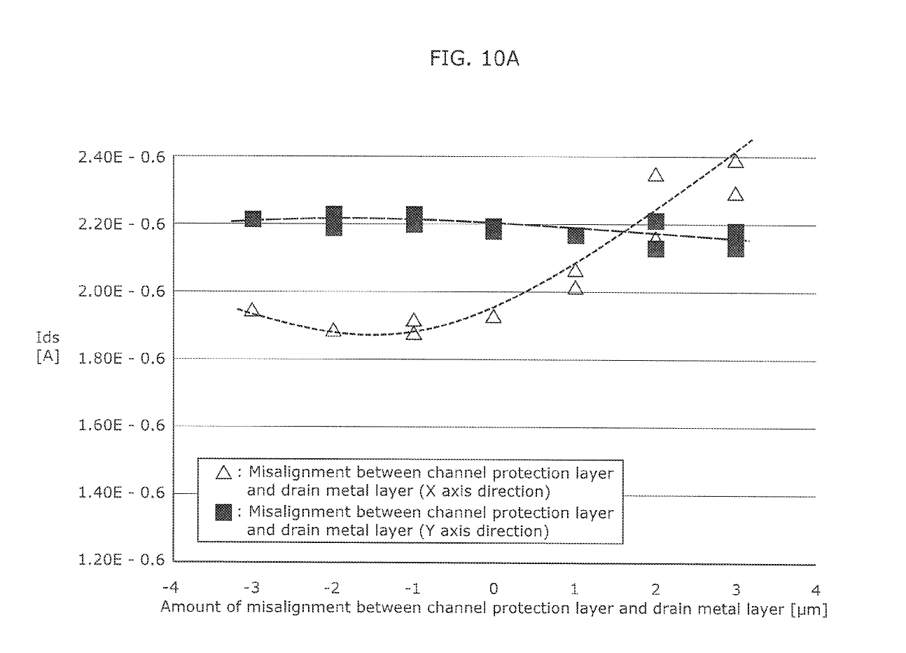

FIG. 7 is an example of a plan view showing a difference in the overlapping area due to misalignment. FIG. 8 and FIG. 9 each are a diagram illustrating tilt of a lens of an exposure apparatus and the resulting deformation of an exposure pattern in a transistor fabrication process.

If a lens 200 is tilted from the correct position during the formation of a transistor Tr, an exposure pattern formed through a mask 210 is deformed and the positional displacement occurs between the exposure pattern and the glass substrate 100, as shown in FIG. 8 and FIG. 9. This reveals that tilt and misalignment of the lens 200 causes deformation of the exposure pattern thus formed, as in the case where misalignment of the mask 210 occurs. As described above, not only ensuring the alignment of the mask 210 but also keeping the lens 200 in a fixed position without being tilted to ensure its alignment is considered Important for the positional accuracy of the exposure pattern thus formed.

In FIG. 6, (b) shows the case where alignment is achieved ideally. In contrast, in FIG. 7, (a) and (b) show the case where the drain metal layer 103 is misaligned with a stack of the gate metal layer 101, the semiconductor layer 102, and the channel protection film 108 and the case where the source metal layer 104 is misaligned with the stack, respectively. In (b) of FIG. 6, the overlapping regions Sgs0a and Sgd0a, the overlapping regions Sgs0b and Sgd0b, and the overlapping regions Sgs0c and Sgd0c have approximately the same size. In (a) of FIG. 7, however, the overlapping region Sgs1a is smaller than the overlapping region Sgd1a, and in (b) of FIG. 7, the overlapping region Sgs2a is larger than the overlapping region Sgd2a. In (b) of FIG. 6, the magnitude of the parasitic capacitance Cgs0 is approximately equal to that of the parasitic capacitance Cgd0. However, the parasitic capacitance Cgs1 is smaller than the parasitic capacitance Cgd1 in (a) of FIG. 7, and the parasitic capacitance Cgs2 is greater than the parasitic capacitance Cgd2 in (b) of FIG. 7.

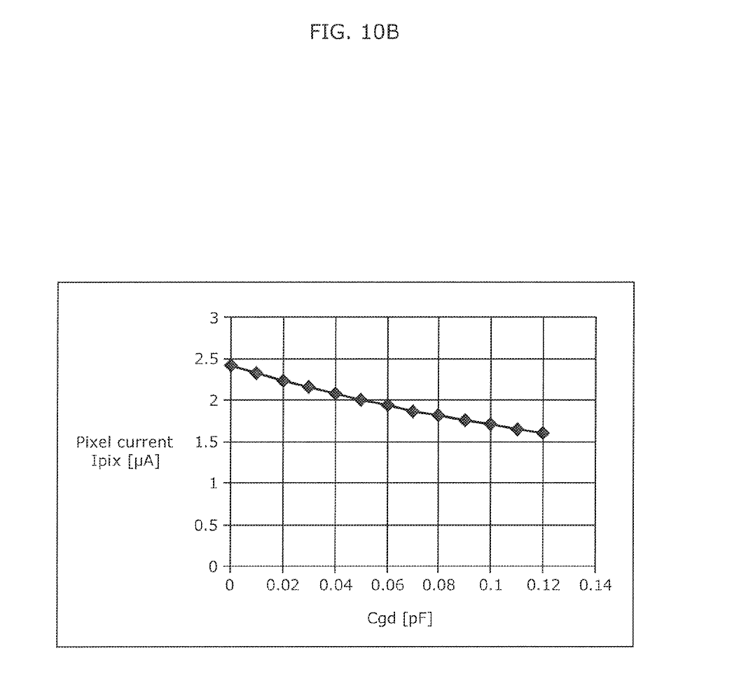

FIG. 10A is a graph showing a relationship between an amount of misalignment between the channel protection film 108 and the drain metal layer 103 and a transistor current Ids flowing between the source and the drain. As for the drain metal layer 103 and the source metal layer 104, as shown in FIG. 10A, as the amount of misalignment in the positive direction of the X axis increases, that is, as the overlapping regions Sgd0a, Sgd1a, and Sgd2a between the drain-side channel protection film 108 and the drain metal layer 103 increases, the current Ids flowing between the source and the drain increases. This is because: a change in the area of the drain-side overlapping region in the channel region causes a change in the carrier concentration (a change in the current density) in the overlapping region, resulting in a change in the effective gate length L. This means that, in a CES transistor, when the area of the drain-side overlapping region in the channel region changes due to misalignment, a current Ids flowing between the source and the drain changes.

In Comparative Example 1 shown in FIG. 4, even if the misalignment causes a difference between the sizes of the overlapping regions Sgs0a and Sgd0a, the change in the overlapping regions Sgs0a and Sgd0a occurs in the same direction in all the transistors because the source electrodes and the drain electrodes are arranged in the same order in all the transistors. Therefore, the amount of the current Ids between the source and the drain of the driving transistor changes in the same direction in all the sub-pixels, and thus the driving transistors of all the sub-pixels have the same characteristics. However, Comparative Example 1 has a drawback that the layout area of each sub-pixel cannot be reduced sufficiently.

In contrast, in Comparative Example 2 shown in FIG. 5, the layout area of each sub-pixel can be reduced so as to increase the degree of integration. If misalignment occurs in Comparative Example 2, however, the overlapping regions Sgs0a and Sgd0a in the odd-numbered columns are shifted in a direction opposite to the direction in which the overlapping regions Sgs0a and Sgd0a in the even-numbered columns are shifted, and thus the source-drain current of the driving transistors in the odd-numbered columns changes in a direction opposite to the direction in which the current in the even-numbered columns change. Specifically, in the case of (a) of FIG. 7, the area of the drain-side overlapping region Sgd1a increases and thus the current Ids also increases. In the case of (b) of FIG. 7, the area of the drain-side overlapping region Sgd2a decreases and thus the current Ids also decreases.

Therefore, if the same gray scale level is applied to both the odd-numbered and even-numbered columns, the display of one of the odd-numbered and even numbered columns is relatively bright, while the display of the other thereof is relatively dark, which is disadvantageous. The display in the case of (a) of FIG. 7 is relatively bright, while the display in the case of (b) of FIG. 7 is relatively dark. This uneven brightness may cause streaks to appear in the organic EL panel 10.

### (Change in Input/Output Characteristics of Pixel Circuit)

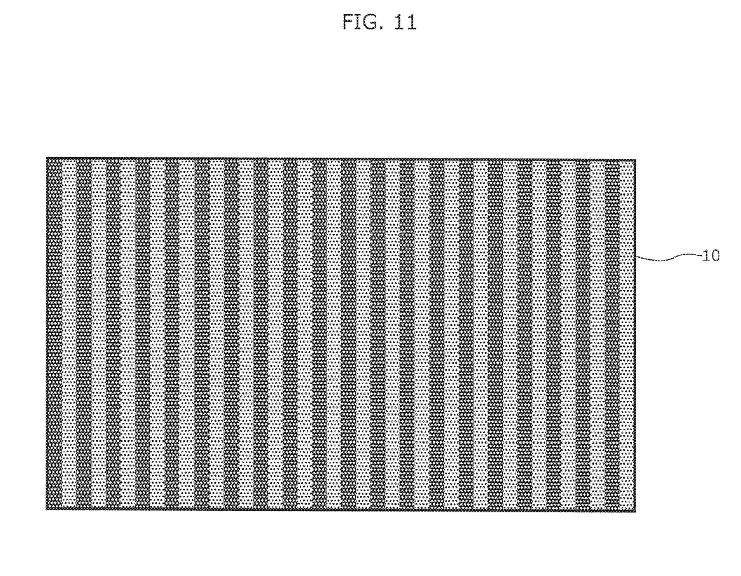

On the other hand, FIG. 10B is a graph showing a relationship between the magnitude of a parasitic capacitance Cgd and the magnitude of a pixel current Ipix that flows into an organic EL element OEL through a driving transistor Trd when a display is performed with a gray scale characteristic of the pixel circuit in FIG. 3. As shown in FIG. 11, in the drain metal layer 103 and the source metal layer 104, as the amount of misalignment in the positive direction of the X axis increases, that is, as the drain-side parasitic capacitance Cgd increases, the pixel current Ipix decreases. This relationship can be explained by the following formulae (1) and (2).

$$\begin{matrix} [ Math . 1 ] & \\ Ipix = \frac{1}{2} μ Cox \frac{W}{L} {( Vgs - Vth )}^{2} & Formula ( 1 ) \\ Vgs = \{ ( Vdata - Vs\_write ) - ( Vemit + VEL - Vs\_write ) \cdot ( \frac{Cgd}{Cs + Cgs + Cgd} ) \} & Formula ( 2 )\end{matrix}$$

Formula 1 and Formula 2 show the input/output characteristics of the pixel circuit in FIG. 3. In Formula 1, μ represents the degree of mobility of the driving transistor Trd, Cox represents the capacitance per unit area of a gate oxide film, W represents the gate width of the driving transistor Trd, L represents the gate length, Cs, Cgs, and Cgd represent the values of the capacitance of a capacitor Cs, the parasitic capacitance Cgs, and the parasitic capacitance Cgd, respectively. Vdata represents a signal voltage written into the capacitor Cs from a data signal line DR through a switching transistor Trs, VEL represents a voltage input to a cathode electrode, Vemit represents a voltage between an anode electrode and a cathode electrode of an organic EL element OEL during light emission, and Vs_write represents a potential produced on the source side of the driving transistor Trd by a power supply line on the high potential side (a line for supplying a power supply voltage VTFT in FIG. 3) through the driving transistor Trd when the signal voltage is written.

As can be seen from Formula 1 and Formula 2, as the parasitic capacitance Cgd increases, Vgs decreases and thus the pixel current Ipix decreases. This is attributed to a phenomenon called bootstrapping. Bootstrapping is a phenomenon in which after a signal voltage is written and before light emission is started, the potential at the source of the driving transistor Trd changes and the potential at the gate of the driving transistor Trd also changes in accordance with the change at the source (see Patent Literature (PTL) 2). In this case, the potential at the gate of the driving transistor Trd does not change in full accordance with the change in the potential at the source of the driving transistor Trd. Instead, voltage loss occurs depending on the accumulated capacitance Cs and the parasitic capacitances Cgs and Cgd of the driving transistor Trd. Formula 1 and Formula 2 show the input/output characteristics of the pixel circuit that are corrected in view of voltage loss by bootstrapping. This means that, in a pixel circuit that has a transistor structure including parasitic capacitances Cgs and Cgd and performs bootstrapping, as shown in FIG. 3, when the magnitudes of the magnitude of the parasitic capacitances change due to misalignment, the pixel current Ipix also changes.

In Comparative Example 1 shown in FIG. 4, even if the misalignment causes a difference between the parasitic capacitances Cgs0 and Cgd0, the change in the parasitic capacitances Cgs0 and Cgd0 occurs in the same direction in all the sub-pixel circuits because the source electrode and the drain electrode are arranged in the same order in all the sub-pixel circuits, as in the case of the change in the overlapping regions as described above. Therefore, the amount of pixel current Ipix changes in the same direction in all the sub-pixels, and thus the pixel circuits of all the sub-pixels have the same input/output characteristics. However, Comparative Example 1 has a drawback that the layout area of each sub-pixel cannot be reduced sufficiently.

In contrast, in Comparative Example 2 shown in FIG. 5, the layout area of each sub-pixel can be reduced so as to increase the degree of integration. In Comparative Example 2, however, the parasitic capacitances Cgs0 and Cgd0 in the odd-numbered columns are shifted in a direction opposite to the direction in which the parasitic capacitances Cgs0 and Cgd0 in the even-numbered columns are shifted, and thus the pixel current in the odd-numbered columns changes in a direction opposite to the direction in which the pixel current in the even-numbered columns changes. Specifically, in the case of (a) of FIG. 7, the drain-side parasitic capacitance Cgd1 increases and thus the pixel current Ipix decreases. In the case of (b) of FIG. 7, the area of the drain-side parasitic capacitance Cgd2 decreases and thus the pixel current Ipix increases.

Therefore, if the same gray scale level is applied to both the odd-numbered and even-numbered columns, the display of one of the odd-numbered and even numbered columns is relatively bright, while the display of the other thereof is relatively dark, which is disadvantageous. The display in the case of (a) of FIG. 7 is relatively dark, while the display in the case of (b) of FIG. 7 is relatively bright. Thus, streaks may occur in the organic EL panel 10.

FIG. 11 is a diagram illustrating an example of streaks. In Comparative Example 2, the characteristics of transistors vary from column to column, that is, an increase and a decrease in the current Ids occur in alternate columns, and thus streaks occur in the column direction.

In addition, in the organic EL panel 10, sets of three color (red, blue, and green) columns are repeatedly arranged. Therefore, in the same color sub-pixel columns, bright sub-pixel columns and dark sub-pixel columns are alternately arranged, resulting in disadvantageous variations in chrominance between the sub-pixels of the same color. In this case, for example, it may be possible to adjust the gray scale level on a software basis, but such adjustment requires various corrections for each column, resulting in an increase in the processing load on the organic EL display.

Furthermore, in a large-sized organic EL display 1, not a single lens (an exposure source) but a plurality of lenses may be used to form a source metal layer, a drain metal layer, and a gate metal layer. In such a case, the amount of misalignment varies from lens to lens, and thus streaks are more visible than the case where a single lens is used, which is disadvantageous.

It should be noted that a change in the transistor current Ids caused by a change in the overlapping regions Sgd0a, Sgd1a, and Sgd2a between the channel protection film 108 and the drain metal layer 103 and a change in the overlapping regions Sgs0a, Sgs1a, and Sgs2a between the channel protection film 108 and the source metal layer 104 may occur independently of a change in the input/output characteristics of the pixel circuit caused by a change in the parasitic capacitances Cgs and Cgd, and the above description is merely an example. This is because misalignment occurs randomly in any combination of layers and does not always occur in the combination of layers as shown in FIG. 7. Therefore, it is important to address both a change in the transistor current Ids and a change in the pixel circuit input/output characteristics.

### Comparative Example 3

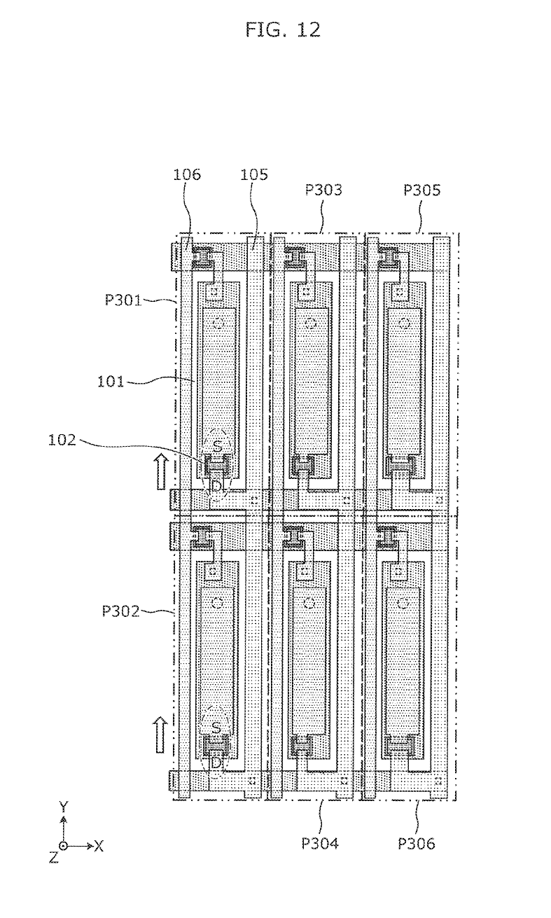

FIG. 12 is a diagram illustrating an example of a layout of an organic EL panel according to Comparative Example 3. FIG. 12 shows sub-pixels P301 to P306 that are arranged in two rows and three columns. The shape, size, and location of each component of the sub-pixels P301 to P 306 are approximately the same.

The layout shown in FIG. 12 has the same drawback as that of Comparative Example 1 shown in FIG. 4 that the area is not reduced sufficiently. Therefore, it may be possible to adopt a configuration, as in Comparative Example 2 shown in FIG. 5, in which pairs of symmetrically arranged sub-pixels are laid out in each row and a main power supply line of a power supply line is disposed on the boundary line between the sub-pixels of each pair, so as to increase the degree of integration.

### Comparative Example 4

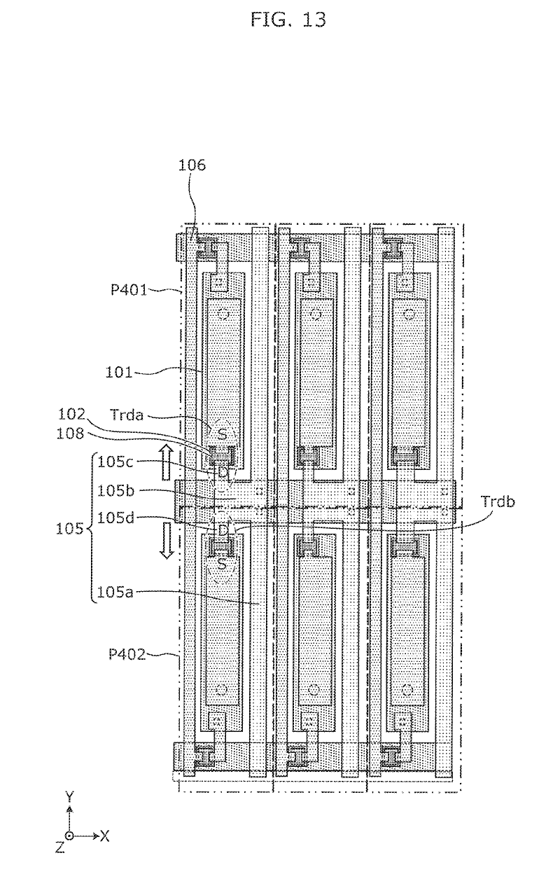

FIG. 13 is a diagram illustrating an example of a layout of an organic EL panel according to Comparative Example 4. In FIG. 13, two sub-pixels P401 and P402 that are adjacent to each other in the column direction are laid out symmetrically. In Comparative Example 4, a power source line 105 includes: a first main power supply line 105a having a long length and extending in the column direction; a second main power supply line 105b having a long length and extending in the row direction; a first sub power supply line 105c extending from the first main power supply line 105a to a drain electrode of a driving transistor Trda of the sub-pixel P401; and a second sub power supply line 105d extending from the first main power supply line 105a to a drain electrode of a driving transistor Trdb of the sub-pixel P402. The first main power supply line 105a and the second main power supply line 105b are connected with each other by a contact. The second main power supply line 105b is disposed on the boundary line between the sub-pixel P401 and the sub-pixel P402 that are adjacent to each other in the column direction.

In Comparative Example 4, the second main power supply line 105b is provided not in each row but in alternate rows, and thus the area of the sub-pixels is reduced and the degree of integration is increased.

However, as shown in FIG. 13, also in the case of Comparative Example 4, the locations of the source electrode and the drain electrode are vertically symmetrical in FIG. 13, as in the case of Comparative Example 2. Therefore, misalignment causes the transistor characteristics and the pixel circuit input/output characteristics to vary on a row-by-row basis. In this case, it is considered that streaks occur in the row direction of the organic EL panel 10.

Accordingly, there is a need for a technique for increasing the degree of integration and preventing variations in the characteristics of sub-pixels due to misalignment.

Hereinafter, the embodiment will be described in detail with reference to the drawings as appropriate. It should be noted that detailed description more than necessary may be omitted. For example, a detailed description of already well-known matters and a redundant description of substantially the same configuration may be omitted. This is to avoid the following description from becoming unnecessarily redundant and to allow any person skilled in the art to easily understand the description.

It should be noted that the present Inventors provide the following description and the accompanying drawings to allow any person skilled in the art to fully understand the present disclosure and thus do not Intend to limit the subject matter described in the claims by the following description and the accompanying drawings.

### Embodiment

Hereinafter, the embodiment will be described with reference to FIG. 1 to FIG. 3 and FIG. 14. In the present embodiment, the case where the display device is an organic EL display will be described as an example.

In the organic EL display according to the present embodiment, a main power supply line of a power supply line for supplying a driving voltage to driving transistors is disposed on the boundary line between two adjacent sub-pixels so as to increase the degree of integration. Furthermore, in the organic EL display according to the present embodiment, a current is allowed to flow in the same direction between the sources and the drains of all the driving transistors so as to prevent variations in the characteristics of the sub-pixels due to misalignment. In other words, the driving transistors of the two adjacent sub-pixels are oriented in the same direction so as to obtain the above-mentioned advantageous effects.

It should be noted that the direction of the current is the physical direction of motion (the direction of motion in the layout) in the organic EL panel and the direction from the drain electrode to the source electrode. The phrase “the driving transistors are oriented in the same direction” means that the driving transistors are physically oriented in the same direction in the organic EL panel (in the layout). In other words, in the case where the directions from the drain electrode to the source electrode in the driving transistors of the above two sub-pixels are the same as each other, it is understood that these driving transistors are oriented in the same direction.

In the present embodiment, the appearance and basic configuration of the organic EL display 1 are the same as those in Comparative Example 1. As shown in FIG. 1 and FIG. 2, the organic EL display 1 includes an organic EL panel 10, a data line driving circuit 20, a scanning line driving circuit 30, and a timing controller (hereinafter abbreviated as “TCON”) 40.

### 1. Configuration of Organic EL Panel

As shown in FIG. 2, the organic EL panel 10 includes a plurality of data signal lines DR1 to Drn, DG1 to DGn, and DB1 to DBn extending in the column direction, a plurality of scanning signal lines Scan1 to Scanm extending in the row direction, and a plurality of pixels P respectively disposed at the intersections between the plurality of data signal lines and the plurality of scanning signal lines. In other words, the plurality of pixels P are arranged in a matrix with m rows and n columns.

The pixels P each include a sub-pixel PR that emits red (R) light, a sub-pixel PG that emits green (G) light, and a sub-pixel PB that emits blue (B) light. The basic configuration of the sub-pixels PR, PG, and PB is the same as that in Comparative Example 1.

Hereinafter, the configuration of the sub-pixels PR, PG, and PB will be described with reference to FIG. 3. It should be noted that the sub-pixels PR, PG, and PB have the same configuration except for color filters. Therefore, the configuration of the sub-pixel PR except for a color filter will be described and the description of the other sub-pixels is omitted.

FIG. 3 is a circuit diagram illustrating an example of the configuration of the sub-pixel PR. As shown in FIG. 3, the sub-pixel PR includes an organic EL element OEL, a capacitor Cs, a switching transistor Trs, and a driving transistor Trd.

The organic EL element OEL Is a light-emitting element that emits light depending on a driving current. In the present embodiment, the organic EL element OEL is a light-emitting element that outputs white light. The driving current is supplied from the driving transistor Trd. In the organic EL element OEL, its anode electrode is connected to the source electrode of the driving transistor Trd, and its cathode electrode receives an input of a power supply voltage VEL (which is, for example, a ground voltage).

The capacitor Cs is a capacitor in which electric charge corresponding to the voltage of the data signal line DR is accumulated. In the capacitor Cs, the first electrode is connected to the gate electrode of the driving transistor Trd, and the second electrode is connected to a connection node Ns between the anode terminal of the organic EL element OEL and the source electrode of the driving transistor Trd.

It should be noted that as shown in Formula 1 and Formula 2, the voltage accumulated in the capacitor Cs varies depending on the parasitic capacitance Cgs formed between the gate and the source of the driving transistor Trd and the parasitic capacitance Cgd formed between the gate and the drain of the driving transistor Trd.

The driving transistor Trd supplies, to the organic EL element OEL, a driving current corresponding to the amount of the electric charge accumulated in the capacitor Cs according to the voltage of the data signal line DR. The driving transistor Trd is a thin film transistor. Its gate electrode is connected to the first electrode of the capacitor Cs and its source electrode is connected to the anode electrode of the organic EL element OEL, and its drain electrode receives an input of a power supply voltage VTFT. It should be noted that a parasitic capacitance Cgd is formed between the gate and the drain of the driving transistor Trd, and a parasitic capacitance Cgs is formed between the gate and the source of the driving transistor Trd.

The switching transistor Trs is a switching element that switches between conduction and non-conduction between the data signal line DR and the first electrode of the capacitor Cs according to the voltage of the scanning signal line Scan. More specifically, the switching transistor Trs is a thin film transistor. Its gate electrode is connected to the scanning signal line Scan, its source electrode is connected to the data signal line DR, and its drain electrode is connected to a connection node Ng between the first electrode of the capacitor Cs and the gate voltage of the driving transistor Trd.

Furthermore, as shown in FIG. 2, in the present embodiment, the sub-pixels PR, PG, and PB are arranged in this order in the pixel P in the row direction.

In a region where the sub-pixel PR is formed, a color filter that transmits light in a red wavelength range is formed on the front side of the organic EL element OEL. Likewise, in a region where the sub-pixel PG is formed, a color filter that transmits light in a green wavelength range is formed on the front side of the organic EL element OEL. In a region where the sub-pixel PB is formed, a color filter that transmits light in a blue wavelength range is formed on the front side of the organic EL element OEL. With this configuration, the sub-pixels PR, PG, and PB can be formed.

It should be noted that the color filters may be formed by, for example, mask deposition, but the method for forming the color filters is not limited to this example. For example, it is possible to form organic EL elements for blue light emission and provide color conversion layers (color changing media (CCM)) for converting the blue light into red (R) light, green (G) light, and blue (B) light, respectively.

Furthermore, in the present embodiment, a configuration in which each of the sub-pixels includes a white organic EL element OEL and a color filter that transmits light of a color corresponding to the sub-pixel is described, but the present disclosure is not limited to this configuration. For example, each of the organic EL elements OEL may be formed using a material suitable for the corresponding color.

Furthermore, in the present embodiment, a configuration in which the switching transistor Trs and the driving transistor Trd are both thin film transistors is described as an example, but the present disclosure is not limited to this configuration. The switching transistor Trs and the driving transistor Trd each may be a FET, MOS-FET, MOS transistor, bipolar transistor, or the like. Furthermore, the switching transistor Trs is not limited to a transistor, and may be an analog switch or the like.

### 2. Configurations of Data Line Driving Circuit, Scanning Line Driving Circuit, and TCON

The data line driving circuit 20 is a circuit that applies data signals to source lines in response to a first control signal from a TCON 40.

The scanning line driving circuit 30 applies, to each scanning signal line Scan, a scanning signal for turning ON or OFF a switching transistor Trs connected to the scanning signal line Scan, in response to a second control signal from the TCON 40.

The TCON 40 is an example of a controller that controls the display of a video image using a plurality of pixels P. The TCON 40 has a function of controlling the data line driving circuit 20 and the scanning line driving circuit 30. During the display operation, the TCON 40 outputs a first control signal having a voltage value corresponding to an externally input image signal to the data line driving circuit 20 and outputs a second control signal to the scanning line driving circuit 30.

It should be noted that, in the present embodiment, a configuration in which the TCON 40 is a dedicated large scale integrated circuit (LSI) is described as an example, but the present disclosure is not limited to this configuration. The TCON 40 may be a computer system including, for example, a microprocessor (MPU), a ROM, a RAM, and the like. In this case, the microprocessor operates according to a computer program for executing the above-mentioned operations and the above-mentioned operations are thus performed.

### 3. Layout

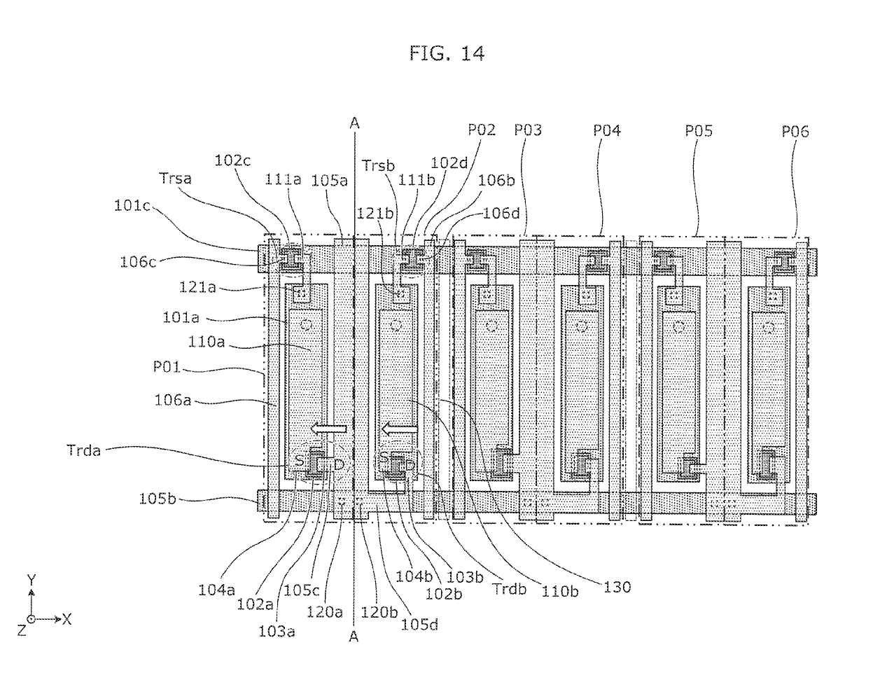

FIG. 14 is a layout diagram illustrating the layout of pixels according to the present embodiment.

As shown in FIG. 14, the organic EL panel 10 includes a sub-pixel P01 (an example of a first pixel) and a sub-pixel P02 (an example of a second pixel) that are arranged adjacent to each other. The organic EL panel 10 further includes a power supply line for supplying a power supply voltage VTFT to a driving transistor of each of the sub-pixels. The power supply line includes: a first main power supply line 105a extending in the column direction; a second main power supply line 105b extending in the row direction; a first sub power supply line 105c extending from the first main power supply line 105a to a drain electrode of a driving transistor Trda; and a second sub power supply line 105d extending from the first main power supply line to a drain electrode of a driving transistor Trdb.

It should be noted that in the layout diagram shown in FIG. 14, six sub-pixels P01 to P06 that are aligned in the row direction are shown. The sub-pixels P01 and P02, the sub-pixels P03 and P04, and the sub-pixels P05 and P06, respectively, form pairs. Therefore, the pair of the sub-pixels P01 and P02 is described below. The configuration of the other pairs is the same as that of the pair of the sub-pixels P01 and P02, and the description thereof is omitted.

The components of the sub-pixel P01 are arranged symmetrically to the components of the sub-pixel P02 with respect to a boundary line AA between the sub-pixels P01 and P02, except for the first and second sub power supply lines 105c and 105d and the driving transistors Trda and Trdb. The shapes and sizes of the components of the sub-pixel P01 are mirror-reversed to those of the components of the sub-pixel P02 with respect to the boundary line AA as the axis, except for the shapes and sizes of the first sub power supply line 105c and the driving transistor Trda of the sub-pixel P01 and those of the second sub power supply line 105d and the driving transistor Trdb of the sub-pixel P02. The boundary line AA is a line parallel to the column direction (Y axis).

FIG. 14 shows the power supply line and the layers corresponding to the gate metal layer 101, the semiconductor layer 102, the drain metal layer 103, and the source metal layer 104 shown in (b) of FIG. 6.

Among the layers shown in FIG. 14, the layers corresponding to the gate metal layer 101 (i.e., gate metal layers 101a to 101c) and the second main power supply line 105b are located in the same layer. On the positive side of the Z axis from these layers, semiconductor layers 102a to 102d are located in the same layer. On the more positive side of the Z axis from the semiconductor layers 102a to 102d, metal layers 110a and 110b, a first main power supply line 105a, a first sub power supply line 105c, a second sub power supply line 105d, data signal lines 106a and 106b, and metal layers 111a and 111b are arranged.

The gate metal layer 101a is a gate metal layer that forms the gate electrode of the driving transistor Trda and a gate line extending from the gate electrode. A surface of the gate metal layer 101a which is parallel to the XY plane has a rectangular shape. The short side length (the length of the side parallel to the X axis) of the gate metal layer 101a is shorter than the distance between a later-described data signal line 106a and the first main power supply line 105a (the distance in the X axis direction H_sub_sd). The longer side length (the length of the side parallel to the Y axis) of the gate metal layer 101a is shorter than the distance between the gate metal layer 101c and the second main power supply line 105b (the distance in the Y axis direction L_sub_sd). The gate metal layer 101a is disposed in a central region of the sub-pixel P01 not to overlap the data signal line 106a, the first main power supply line 105a, the gate metal layer 101c, and the second main power supply line 105b.

The gate metal layer 101b is a gate metal layer that forms the gate electrode of the driving transistor Trdb and a gate line extending from the gate electrode. The shape, size, and location of the gate metal layer 101b are mirror-reversed to those of the gate metal layer 101a with respect to the boundary line AA.

The gate metal layer 101c is a gate metal layer that forms the gate electrode of the switching transistor Trsa, the gate electrode of the switching transistor Trsb, and a scanning signal line connected to these electrodes (corresponding to any one of the scanning signal lines Scan in FIG. 2). As shown in FIG. 14, the gate metal layer 101c is a long layer extending in the raw direction (X axis direction). The gate metal layer 101c is provided in each row in common to the plurality of sub-pixels aligned in the raw direction. The gate metal layer 101c is disposed in an edge region on the positive side of the Y axis in the row of sub-pixels.

The second main power supply line 105b is a power supply line for supplying a power supply voltage VTFT (see FIG. 3) to a plurality of sub-pixels. As shown in FIG. 14, the second main power supply line 105b is a long power supply line extending in the row direction. The second main power supply line 105b is provided in each row, and supplies a power supply voltage VTFT to the plurality of sub-pixels aligned in the row direction. The second main power supply line 105b is disposed to pass through an edge region on the negative side of the Y axis in the row of the sub-pixels. The second main power supply line 105b is connected to the first main power supply line 105a by contacts 120a and 120b.

The semiconductor layer 102a is a semiconductor layer (corresponding to the semiconductor layer 102 in FIG. 6) that constitutes the driving transistor Trda of the sub-pixel P01. As shown in FIG. 14, a surface of the semiconductor layer 102a which is parallel to the XY plane has a rectangular shape. The area of the semiconductor layer 102a is significantly smaller than the area of the gate metal layer 101a. The semiconductor layer 102a is disposed within the region of the gate metal layer 101a as seen from the positive side of the Z axis and in the lower portion of the gate metal layer 101a in FIG. 14 (on the negative side of the Y axis).

The semiconductor layer 102b is a semiconductor layer (corresponding to the semiconductor layer 102 in FIG. 6) that constitutes the driving transistor Trdb of the sub-pixel P02. As shown in FIG. 14, a surface of the semiconductor layer 102b which is parallel to the XY plane has a rectangular shape. The area of the semiconductor layer 102b is approximately equal to that of the semiconductor layer 102a and is significantly smaller than the area of the gate metal layer 101b. The semiconductor layer 102b is disposed within the region of the gate metal layer 101b as seen from the positive side of the Z axis and in the lower portion of the gate metal layer 101b in FIG. 14 (on the negative side of the Y axis).

The semiconductor layer 102c is a semiconductor layer that constitutes the switching transistor Trsa of the sub-pixel P01. A surface of the semiconductor layer 102c which is parallel to the XY plane has a rectangular shape. The semiconductor layer 102c is disposed within the region of the gate metal layer 101c as seen from the positive side of the Z axis and in the vicinity of the data signal line 106a.

The semiconductor layer 102d is a semiconductor layer that constitutes the switching transistor Trsb of the sub-pixel P02. The shape, size, and location of the semiconductor layer 102d are mirror-reversed to those of the semiconductor layer 102c with respect to the boundary line AA.

The metal layer 110a (the source metal layer 104a) is a layer that forms the source electrode of the driving transistor Trda of the sub-pixel P01 and a line extending from the source electrode. A surface of the metal layer 110a which is parallel to the XY plane has a rectangular shape with a rectangular cutout at a lower right corner in FIG. 14 (on the negative side of the Y axis and on the positive side of the X axis). The lengths of the metal layer 110a in the X axis direction and the Y axis direction are shorter than the lengths of the gate metal layer 101a in the X axis direction and the Y axis direction. The metal layer 110a is disposed within the region of the gate metal layer 101a. In other words, the gate metal layer and the source metal layer are stacked on one another in the Z axis direction.

It should be noted that the semiconductor layer 102a is disposed in the cutout portion of the metal layer 110a. The semiconductor layer 102a is disposed such that a portion of the semiconductor layer 102a including its left side (the side on the negative side of the X axis) overlaps the side of the cutout portion of the metal layer 110a which is parallel to the Y axis.

The metal layer 110b (the source metal layer 104b) is a layer that forms the source electrode of the driving transistor Trdb of the sub-pixel P02 and a line extending from the source electrode. A surface of the metal layer 110b which is parallel to the XY plane has a rectangular shape with a rectangular cutout at a lower right corner in FIG. 14 (on the negative side of the Y axis and on the positive side of the X axis). The lengths of the metal layer 110b in the X axis direction and the Y axis direction are shorter than the lengths of the gate metal layer 101b in the X axis direction and the Y axis direction. It should be noted that the shape of the metal layer 110b is not symmetrical to that of the metal layer 110a. The metal layer 110b is disposed within the region of the gate metal layer 101b. In other words, the gate metal layer and the source metal layer are stacked on one another in the Z axis direction.

It should be noted that the semiconductor layer 102b is disposed in the cutout portion of the metal layer 110b. The semiconductor layer 102b is disposed such that a portion of the semiconductor layer 102b including its left side (the side on the negative side of the X axis) overlaps the side of the cutout portion of the metal layer 110b which is parallel to the Y axis.

The first main power supply line 105a is a power supply line for supplying a power supply voltage VTFT to a plurality of sub-pixels. The first main power supply line 105a is a long power supply line extending in the column direction. The first main power supply line 105a is provided not in each column but in alternate columns, and supplies a power supply voltage VTFT to sub-pixels in two columns. The first main power supply line 105a is disposed on the boundary line AA between the sub-pixels P01 and P02. As described above, the first main power supply line 105a is connected to the second main power supply line 105b by contacts 120a and 120b.

The first sub power supply line 105c is a rectangular power supply line extending from the first main power supply line 105a to the semiconductor layer 102a of the sub-pixel P01. The end of the first sub power supply line 105c overlaps a portion of the semiconductor layer 102a including its right side, and forms the drain metal layer 103a of the driving transistor Trda.

The second sub power supply line 105d is a hook-like power supply line extending from the first main power supply line 105a to the semiconductor layer 102b of the sub-pixel P02. The end of the second sub power supply line 105d overlaps a portion of the semiconductor layer 102b including its right side, and forms the drain metal layer 103b of the driving transistor Trdb. More specifically, the second sub power supply line 105d includes: a first portion extending in the positive direction of the X axis from the first main power supply line 105a to a position more positive than the right side of the semiconductor layer 102b; a second portion extending in the positive direction of the Y axis from the end of the first portion to the vicinity of the semiconductor layer 102b; and a third portion extending in the negative direction of the X axis from the end of the second portion to the right side of the semiconductor layer 102b (the edge portion on the positive side of the X axis).

In other words, the shape of the first sub power supply line 105c extending from the first main power supply line 105a to the semiconductor layer 102a of the driving transistor Trda is different from the shape of the second sub power supply line 105d extending from the power supply line 105 to the semiconductor layer 102b of the driving transistor Trdb.

The data signal line 106a is a signal line (corresponding to any one of the data signal lines DR, DG, and DB in FIG. 2) for supplying a voltage corresponding to the gray scale level of a video image signal to the column of sub-pixels including the sub-pixel P01. As shown in FIG. 14, the data signal line 106a is a long signal line extending in the column direction and is shared by a plurality of sub-pixels aligned in the column direction. The data signal line 106a is disposed to pass through the edge region on the negative side of the X axis of the sub-pixel P01. The data signal line 106a is provided with a first sub data line 106c extending to the semiconductor 102c. The end of the first sub data line 106c overlaps the left side of the semiconductor layer 102c (the edge portion on the negative side of the X axis).

The data signal line 106b is a signal line (corresponding any one of the data signal lines DR, DG, and DB in FIG. 2) for supplying a voltage corresponding to the gray scale level of a video image signal to the column of sub-pixels including the sub-pixel P02. As shown in FIG. 14, the shape, size, and location of the data signal line 106b are mirror-reversed to those of the data signal line 106a with respect to the boundary line AA. Like the data signal line 106a, the data signal line 106b is provided with a second sub data line 106d extending to the semiconductor layer 102d. The end of the second sub data line 106d overlaps the right side of the semiconductor layer 102d (the edge portion on the positive side of the X axis).

The metal layer 111a is a drain metal layer (corresponding to a line including a node Ng in FIG. 3) that forms a drain electrode of a switching transistor Trsa and a line extending from the drain electrode. As shown in FIG. 14, a surface of the metal layer 111a which is parallel to the XY plane has an approximately rectangular shape with a rectangular cutout in the central portion of the left side. A left part of the end portion of the metal layer 111a on the positive side of the Y axis overlaps the gate metal layer 101c and the semiconductor layer 102c. The metal layer 111a is disposed such that its end portion on the negative side of the Y axis overlaps the gate metal layer 101a, and is connected to the gate metal layer 101a by a contact 121a. In other words, the drain electrode of the switching transistor Trsa is connected to the gate terminal of the driving transistor Trda by the contact 121a.

The metal layer 111b is a drain metal layer (corresponding to a line including a node Ng in FIG. 3) that forms a drain electrode of a switching transistor Trsb and a line extending from the drain electrode. As shown in FIG. 14, the shape, size, and location of the metal layer 111b are mirror-reversed to those of the metal layer 111a with respect to the boundary line AA. The metal layer 111b is disposed such that its end portion on the negative side of the Y axis overlaps the gate metal layer 101b, and is connected to the gate metal layer 101b by a contact 121b. In other words, the drain electrode of the switching transistor Trsb is connected to the gate terminal of the driving transistor Trdb by the contact 121b.

### 4. Advantageous Effects, Etc

In the organic EL display 1 according to the embodiment described above, the sub-pixel P01 (corresponding to the first pixel) and the sub-pixel P02 (corresponding to the second pixel) arranged adjacent to each other each include a driving transistor Trda, Trdb. In the organic EL display 1, the first main power supply line 105a is disposed on the boundary line between the sub-pixels P01 and P02. Thereby, the first main power supply line 105a need not be provided in each column but may be provided in alternate columns. Therefore, the number of the first main power supply lines 105a can be reduced and thus the layout area of the organic EL panel 10 can be reduced and the degree of integration can be increased. Compared to the case where the first main power supply line 105a is not disposed on the boundary line, an area corresponding to the area of a region 130 can be reduced.

Furthermore, in the organic EL display 1 according to the above embodiment, the direction of current flow between the source and the drain of the driving transistor Trda of the sub-pixel P01 is the same as the direction of current flow between the source and the drain of the driving transistor Trdb of the sub-pixel P02. In other words, in the present embodiment, the driving transistor Trda of the sub-pixel P01 and the driving transistor Trdb of the sub-pixel P02 are oriented in the same direction.

Specifically, as seen from FIG. 14, the sub-pixels P01 and P02 according to the present embodiment are both disposed parallel to the X axis (perpendicularly to the boundary line AA) such that the drain electrode and the source electrode are arranged in this order in the negative direction of the X axis. This means that, in both of the sub-pixels P01 and P02 according to the present embodiment, the current flow between the drain and the source is in the negative direction of the X axis. In other words, in the present embodiment, the driving transistor Trda of the sub-pixel P01 and the driving transistor Trdb of the sub-pixel P02 are oriented perpendicularly to the boundary line AA between the sub-pixels P01 and P02.

Therefore, even if, in one of the driving transistors of the sub-pixels P01 and P02, a difference occurs in the overlapping area of the channel protection film and the source electrode and the overlapping area of the channel protection film and the drain electrode or a difference occurs in the parasitic capacitance formed between the gate and the source and the parasitic capacitance formed between the gate and the drain due to misalignment between a mask and an exposure lens, such a difference does not cause a difference in the characteristics of the driving transistors and the input/output characteristics of the pixel circuits between the sub-pixels P01 and P02. Thereby, variations in the chrominance and luminance between sub-pixels can be reduced. A difference in the characteristics of the driving transistors and the input/output characteristics of the pixel circuits may occur between organic EL displays. However, in each organic EL panel or in each group of sub-pixels used to form a metal layer, variations in the Ids characteristics and the pixel circuit input/output characteristics due to misalignment can be prevented and thus variations in the chrominance and luminance can be prevented.

In the present embodiment, the case where the driving transistors Trda and Trdb are bottom-gate transistors having a channel etching stopper (CES) structure is described as an example, but the same applies to bottom-gate transistors having a back channel etching (BCH) structure.

In the CES and BCH structures, when the area of the overlapping region on the drain side of the channel region changes, the carrier concentration in the overlapping region also changes (the current density changes), resulting in a change in the effective gate length L. In other words, in the driving transistors Trda and Trdb having the CES structure or the BCH structures, when the area of the overlapping region on the drain side of the channel region changes due to misalignment, the amount of current flowing between the source and the drain changes. By applying the present embodiment to the organic EL panel 10 including the driving transistors Trda and Trdb having the CES structure or the BCH structure, it is possible to prevent the characteristics of the driving transistor from varying between sub-pixels even if misalignment occurs.

In a bottom-gate transistor, a gate electrode and a source electrode overlap each other and the gate electrode and a drain electrode overlap each other. Therefore, larger parasitic capacitance is formed than in a top-gate transistor. Thus, when the magnitude of the parasitic capacitance changes due to misalignment, the input/output characteristics of the pixel circuit changes. By applying the present embodiment to an organic EL panel including a bottom-gate driving transistor, it is possible to prevent the input/output characteristics of the pixel circuit from varying between sub-pixels even if misalignment occurs.

It should be noted that the driving transistors Trda and Trdb may have a lightly doped drain (LDD) structure or an offset gate structure.

In the case of a driving transistor having a LDD structure, if misalignment occurs when a resist film is formed on the gate metal layer 101 using a photomask, one of the drain-side LDD region and the source-side LDD region may be larger than the other or smaller than the other.

In the case where the direction of current flow between the source and the drain varies between sub-pixels, some of the sub-pixels have a larger drain-side LDD region area and the others have a larger source-side LDD region area. In this case, a larger current flows between the source and the drain of sub-pixels having a larger drain-side LDD region area, while a smaller current flows between the source and the drain of sub-pixels having a larger source-side LDD region area. As a result, the characteristics of the current Ids flowing between the source and the drain of a LDD structure transistor vary between sub-pixels, which is disadvantageous.

In the present embodiment, a current between the source and the drain flows in the same direction in all the sub-pixels. Therefore, the present embodiment does not include a mixture of sub-pixels having a larger drain-side LDD region area and sub-pixels having a larger source-side LDD region area but includes either one of these types of sub-pixels. Thus, the current Ids having the same characteristics is allowed to flow in all the sub-pixels.

Furthermore, unlike Comparative Example 2 shown in FIG. 5, in FIG. 14, currents flow in the same direction only by changing the shape of the second sub power supply line 105d extending from the first main power supply line 105a. Therefore, complication of the layout process can be reduced.

### 5. Variation 1

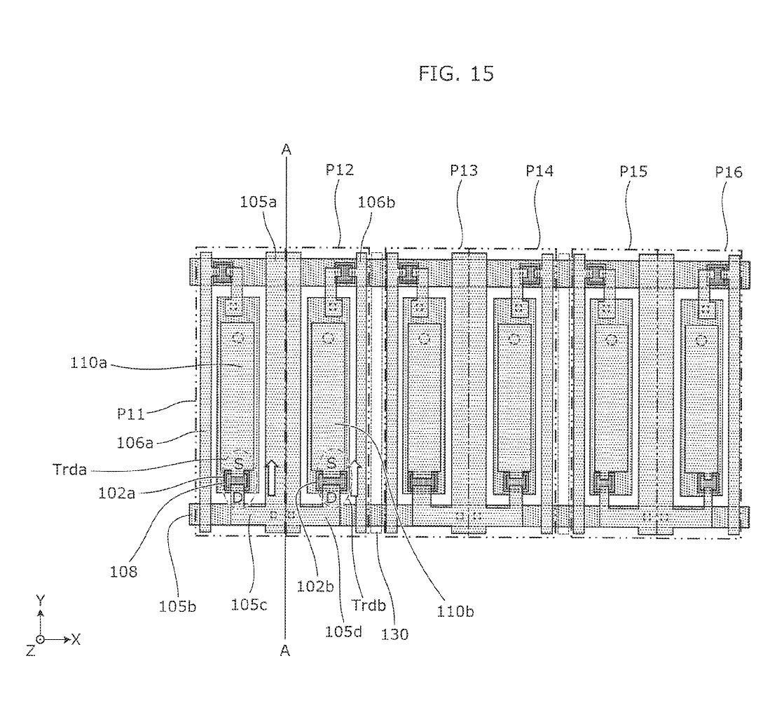

Variation 1 of the embodiment will be described with reference to FIG. 15. In the present variation, the case where the direction of current flow between the source and the drain is different from the direction in the embodiment is described.

FIG. 15 is a layout diagram illustrating a layout of pixels according to the present variation. In the layout diagram of the present variation shown in FIG. 15, six sub-pixels P11 to P16 aligned in the row direction are shown.

The organic EL display 1 of the present variation is different from that of the embodiment in the configurations of the metal layers 110a and 110b of the driving transistors Trda and Trdb and the configurations of the first sub power supply line 105c and the second sub power supply line 105d. The other configurations are the same as those of the embodiment.

As described in the embodiment, the metal layer 110a is a source metal layer that forms the source electrode of the sub-pixel P11. The metal layer 110a has a rectangular surface parallel to the XY plane, and includes a rectangular projection on its short side on the negative side of the Y axis. In the metal layer 110a, the front end portion of the projection overlaps a portion of the semiconductor layer 102a including its upper side (the end portion on the positive side of the Y axis).

In the present variation, the first sub power supply line 105c is formed in an L-shape. The first sub power supply line 105c includes a portion extending in the negative direction of the X axis from the first main power supply line 105a and a portion extending in the positive direction of the Y axis from the end of the former portion. The first sub power supply line 105c is formed such that its end overlaps a portion of the semiconductor layer 102a including its lower side (the end portion of the negative side of the Y axis).

In the present variation, the second sub power supply line 105d has a left-right reversed L-shape. The second sub power supply line 105d includes a portion extending in the positive direction of the X axis from the first main power supply line 105a and a portion extending in the positive direction of the Y axis from the end of the former portion. It should be noted that the shape, size, and location of the first sub power supply line 105c and the shape, size, and location of the second sub power supply line 105d are symmetric with respect to the boundary line AA.

As described in the embodiment, the metal layer 110b is a source metal layer that forms the source electrode of the sub-pixel P02. The shape, size, and location of the metal layer 110b are mirror-reversed to those of the metal layer 110a with respect to the boundary line AA.

As in the above embodiment, the first main power supply line 105a is disposed on the boundary line between the sub-pixels P11 and P12, and thus it is only necessary to provide the first main power supply line 105a in alternate columns. In this case, the area corresponding to a region 130 can be reduced, compared to the case where the first main power supply line 105a is not disposed on the boundary line and provided on a column by column basis.

Furthermore, as shown by arrows in FIG. 15, in both the sub-pixels P11 and P12 of the present embodiment, current between the source and the drain flows in the positive direction of the Y axis (a direction parallel to the boundary line AA). With this configuration, even if misalignment occurs, it is possible to prevent the transistor characteristics and the pixel circuit input/output characteristics from varying between the sub-pixels P11 and P12.

In other words, also in the present variation thus configured, the driving transistor Trda of the sub-pixel P11 and the driving transistor Trdb of the sub-pixel P12 are oriented in the same direction, and thus the same advantageous effects as those of the above embodiment can be obtained. Specifically, in the present variation, the driving transistor Trda of the sub-pixel P11 and the driving transistor Trdb of the sub-pixel P12 are oriented parallel to the boundary line AA between the sub-pixels P11 and P12.

### 6. Variation 2

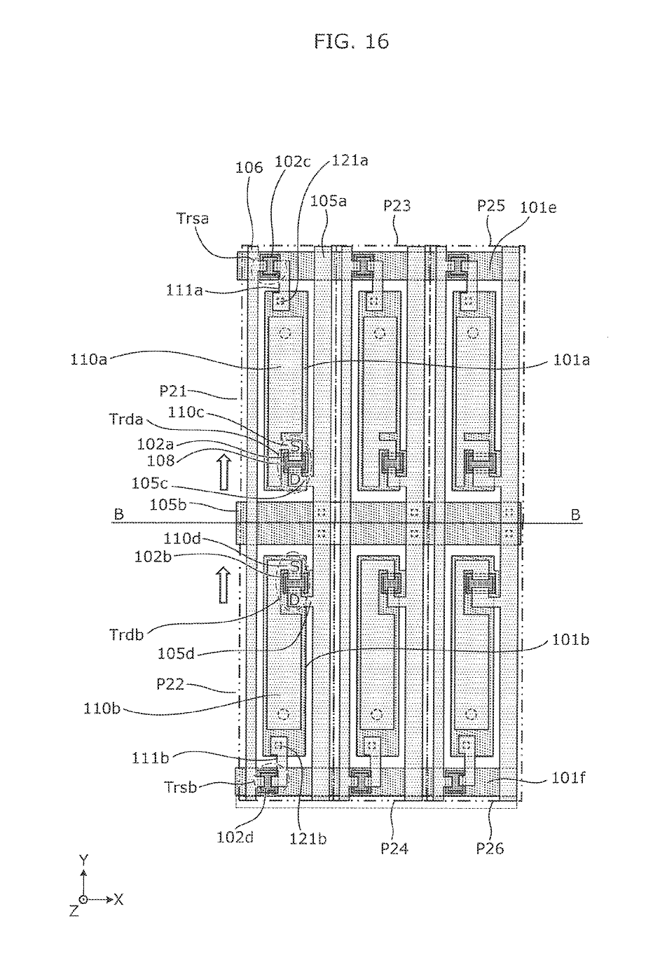

Variation 2 of the embodiment will be described with reference to FIG. 16. In the embodiment and Variation 1, the case where sub-pixels arranged adjacent to each other in the row direction are paired is described, but in the present variation, the case where sub-pixels arranged adjacent to each other in the column direction are paired will be described.

FIG. 16 is a layout diagram illustrating a layout of pixels according to the present variation. In the layout diagram of the present variation shown in FIG. 16, six sub-pixels P21 to P26 arranged in two rows and three columns are shown. A sub-pixel P21 and a sub-pixel P22 adjacent to the sub-pixel P21 on the negative side of the Y axis are paired. Likewise, sub-pixels P23 and P24a are paired and sub-pixels P25 and P26 are paired. Since the pair of sub-pixels P23 and P24 and the pair of sub-pixels P25 and P26 are the same as the pair of sub-pixels P21 and P22, the description thereof is omitted.

In the organic EL panel 10 according to the present variation, the second main power supply line 105b extending in the row direction is disposed on the boundary line between the sub-pixel P21 and the sub-pixel P22. Furthermore, in the organic EL panel 10 according to the present variation, the shape, size, and location of each component of the sub-pixel P21 and those of the sub-pixel P22 are symmetric with respect to the boundary line BB therebetween, except for the driving transistors Trda and Trdb. The boundary line BB is a line parallel to the X axis.

FIG. 16 shows power supply lines and layers corresponding to the gate metal layer 101, the semiconductor layer 102, the drain metal layer 103, and the source metal layer 104 shown in (b) of FIG. 6.

Among the layers shown in FIG. 16, the layers corresponding to the gate metal layer 101 (gate metal layers 101a and 101b and gate metal layers 101e and 101f) and the second main power supply line 105b are located in the same layer. On the positive side of the Z axis of these layers, semiconductor layers 102a to 102d are located in the same layer. On the more positive side of the Z axis from the semiconductor layers 102a to 102d, metal layers 110a and 110b, a first main power supply line 105a, a data signal line 106, and metal layers 111a and 111b are disposed.

The configuration of the gate metal layers 101a and 101b is the same as that of the gate metal layers 101a and 101b of the embodiment.

The gate metal layer 101e is a gate metal layer that forms a gate electrode of a switching transistor Trsa and a scanning signal line (Scan in FIG. 2) connected to the gate electrode. The gate metal layer 101e is a long layer extending in the raw direction (X axis direction). The gate metal layer 101e is provided in each row and connected to a plurality of sub-pixels aligned in the raw direction. The gate metal layer 101e is disposed to pass through an edge region of the sub-pixel P21 on the positive side of the Y axis.

The gate metal layer 101f is a gate metal layer that forms a gate electrode of a switching transistor Trsb and a scanning signal line (Scan in FIG. 2) connected to the gate electrode. The shape, size, and location of the gate metal layer 101f are mirror-reversed to those of the gate metal layer 101e with respect to the boundary line BB. This means that the gate metal layer 101f is disposed to pass through an edge region of the sub-pixel P22 on the negative side of the Y axis.

The second main power supply line 105b is a power supply line for supplying a power supply voltage VTFT to a plurality of sub-pixels. In the present variation, the second main power supply line 105b is a long power supply line extending in the row direction. The second main power supply line 105b is not provided on a row-by-row basis but on an alternate row basis, and supplies a power supply voltage VTFT to sub-pixels of two rows. The second main power supply line 105b is disposed on the boundary line BB between the sub-pixel P21 and the sub-pixel P22. The second main power supply line 105b is connected to the first main power supply line 105a by contacts 120a and 120b.

The semiconductor layers 102a and 102c are the components of the sub-pixel P21 and have the same configuration as those of the embodiment. The semiconductor layers 102b and 102d are the components of the sub-pixel P22. The shapes, sizes, and locations of the semiconductor layers 102b and 102d are mirror-reversed to those of the semiconductor layers 102a and 102c with respect to the boundary line BB.

The metal layer 110a is a source metal layer that forms a source electrode of the sub-pixel P01 and a line connected to the source line. A surface of the metal layer 110a which is parallel to the XY plane has a rectangular shape with a rectangular cutout at a lower right corner in FIG. 16. The lengths of the metal layer 110a in the X axis direction and the Y axis direction are shorter than those of the gate metal layer 101a in the X axis direction and the Y axis direction. The metal layer 110a is disposed within the region of the gate metal layer 101a. In other words, the gate metal layer and the source metal layer are stacked on one another in the Z axis direction.

It should be noted that the semiconductor layer 102a is disposed in the cutout portion of the metal layer 110a. The metal layer 110a is provided with a first sub source line 110c extending from a portion of a side of the cutout portion which is parallel to the Y axis to the upper side of the semiconductor layer 102a. The first sub source line 110c is disposed such that its end overlaps a portion of the semiconductor layer 102a including its upper side.

The metal layer 110b is a source metal layer that forms a source electrode of the sub-pixel P22 and a line connected to the source line. A surface of the metal layer 110b which is parallel to the XY plane has a rectangular shape with a rectangular cutout at an upper right corner in FIG. 16. The lengths of the metal layer 110b in the X axis direction and the Y axis direction are shorter than those of the gate metal layer 101b in the X axis direction and the Y axis direction. The metal layer 110b is disposed within the region of the gate metal layer 101b. In other words, the gate metal layer and the source metal layer are stacked on one another in the Z axis direction.

It should be noted that the semiconductor layer 102b is disposed in the cutout portion of the metal layer 110b. The metal layer 110b is provided with a second sub source line 110d extending from a portion of a side of the cutout portion which is parallel to the Y axis to the upper side of the semiconductor layer 102b. The second sub source line 110d is disposed such that its end overlaps a portion of the semiconductor layer 102b including its upper side.

The first sub source line 110c and the second sub source line 110d have the same shape and size, but their locations are not axisymmetric with respect to the boundary line BB.

The first main power supply line 105a is a power supply line for supplying a power supply voltage VTFT to a plurality of sub-pixels. The first main power supply line 105a is a long power supply line extending in the column direction. The first main power supply line 105a is provided in each column, and supplies a power supply voltage VTFT to sub-pixels in one column. As described above, the first main power supply line 105a is connected to the second main power supply line 105b by contacts.

The first main power supply line 105a is provided with a first sub power supply line 105c having a rectangular shape and extending to the lower side of the semiconductor layer 102a of the sub-pixel P21. The end of the first sub power supply line 105c overlaps a portion of the semiconductor layer 102a including its lower side, and forms the drain electrode of the driving transistor Trda.

Furthermore, the first main power supply line 105a is provided with a second sub power supply line 105d extending to the lower side of the semiconductor layer 102b of the sub-pixel P22. The end of the second sub power supply line 105d overlaps a portion of the semiconductor layer 102b including its lower side, and forms the drain electrode of the driving transistor Trdb.

The data signal line 106 is a signal line for supplying a voltage corresponding to the gray scale level of a video image signal to the column of sub-pixels including the sub-pixels P21 and P22. The data signal line 106 is a long signal line extending in the column direction and is shared by a plurality of sub-pixels aligned in the column direction. The data signal line 106 is disposed to pass through an edge region of the sub-pixels P21 and P22 on the negative side of the X axis.

It should be noted that the data signal line 106 is provided with a first sub source line extending to the semiconductor layer 102c. The end of the first sub source line overlaps the end portion of the semiconductor layer 102c on the negative side of the X axis. Furthermore, the data signal line 106 is provided with a second sub source line extending to the semiconductor layer 102d. The shape, size, and location of the second sub source line are mirror-reversed to those of the first sub source line with respect to the boundary line BB. The end of the second sub source line overlaps the end portion of the semiconductor layer 102d on the negative side of the X axis.

The configuration of the metal layer 111a is the same as that of the metal layer 111a of the embodiment.

The shape, size, and location of the metal layer 111b are mirror-reversed to those of the metal layer 111a with respect to the boundary line BB.

As in the embodiment and Variation 1, the second main power supply line 105b is disposed on the boundary line between the sub-pixels P11 and P12, and thus it is only necessary to provide the second main power supply line 105b in alternate rows. Therefore, the area corresponding to a region 131 can be reduced, compared to the case where the second main power supply line 105 is provided in each row.

Furthermore, as shown by arrows in FIG. 16, in both the sub-pixels P21 and P22 of the present embodiment, current flow between the source and the drain is in the positive direction of the Y axis (a direction perpendicular to the boundary line BB). With this configuration, even if misalignment occurs, it is possible to prevent the transistor characteristics and the pixel circuit input/output characteristics from varying between the sub-pixels P21 and P22.

In other words, also in the present variation thus configured, the driving transistor Trda of the sub-pixel P21 and the driving transistor Trdb of the sub-pixel P22 are oriented in the same direction, and thus the same advantageous effects as those of the above embodiment can be obtained. Specifically, in the present variation, the driving transistor Trda of the sub-pixel P21 and the driving transistor Trdb of the sub-pixel P22 are oriented perpendicularly to the boundary line BB between the sub-pixels P21 and P22.

### 7. Variation 3

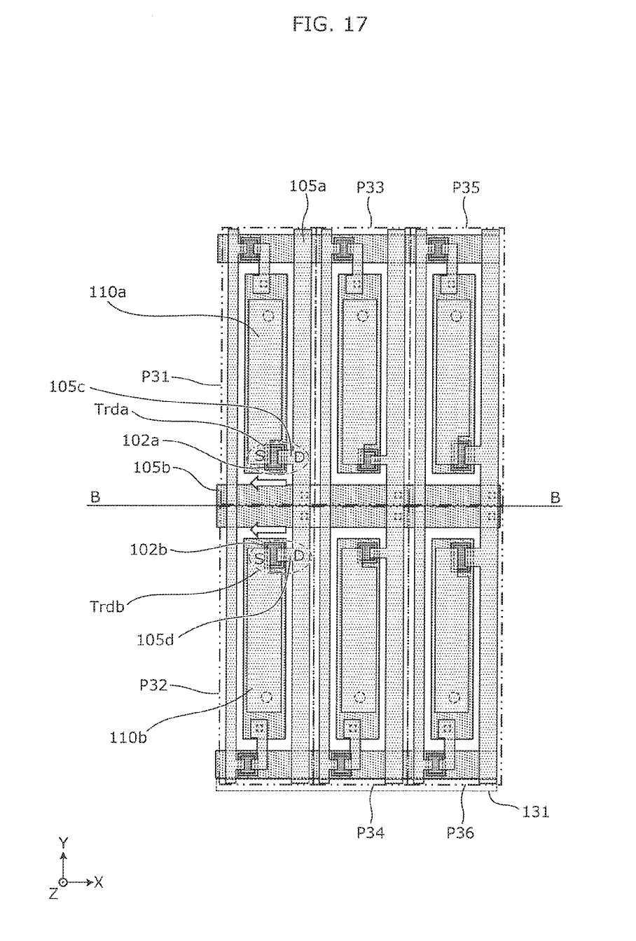

Variation 3 of the embodiment will be described with reference to FIG. 17. In the present variation, the case where two sub-pixels adjacent to each other in the column direction are paired as in the case of Variation 2, but the direction of current flow between the source and the drain is different from that of Variation 2 is described.

Specifically, the case where the direction of current flow between the source and the drain is the positive direction of the Y axis is described in Variation 2, but in the present variation, the case where the direction of current flow between the source and the drain is the negative direction of the X axis is described.

FIG. 17 is a layout diagram illustrating a layout of pixels according to the present variation. In the layout diagram of the present variation shown in FIG. 17, six sub-pixels P31 to P36 arranged in two rows and three columns are shown. A sub-pixel P31 and a sub-pixel P32 adjacent to the sub-pixel P31 on the negative side of the Y axis are paired. Since the other sub-pixels have the same configuration as the sub-pixel P31 or P32, the description thereof is omitted.

Furthermore, the second main power supply line 105b according to the present variation is disposed on the boundary line BB between the sub-pixels P31 and P32, and the shapes, sizes, and locations of the components of the sub-pixel P31 are symmetric to those of the corresponding components of the sub-pixel P32 with respect to the boundary line BB between the sub-pixels P31 and P32. Therefore, in the present variation, the sub-pixel P 31 is described, and the description of the sub-pixel P32 is omitted.

It should be noted that the sub-pixel P31 in the organic EL panel 10 shown in FIG. 17 is different from the sub-pixel P21 in the organic EL panel 10 according to Variation 2 shown in FIG. 16 in the shapes of the metal layer 110a and the first main power supply line 105a. The shapes, sizes, and locations of other layers in the sub-pixel P31 according to the present variation are the same as those of the corresponding layers in the sub-pixel P21 according to Variation 2.

As shown in FIG. 17, the metal layer 110a according to the present variation has a rectangular shape with a rectangular cutout at a lower right corner (on the positive side of the X axis and the negative side of the Y axis). The semiconductor layer 102a is disposed in this cutout portion. A portion of the side of the cutout portion which is parallel to the Y axis overlaps the left-side edge region of the semiconductor layer 102a. A first sub power supply line 105c having a rectangular shape extends from the first main power supply line 105a to the right side of the semiconductor layer 102a.

It should be noted that the shapes, sizes, and locations of the metal layer 110a, the semiconductor layer 102a, and the first sub power supply line 105c in the sub-pixel P31 according to the present variation are substantially the same as those of the metal layer 110a, the semiconductor layer 102a, and the first sub power supply line in the sub-pixel P01 according to the embodiment shown in FIG. 14.

The second main power supply line 105b is disposed on the boundary line BB between the sub-pixels P31 and p32, as in the embodiment and Variations 1 and 2. Therefore, the area corresponding to a region 131 can be reduced, compared to the case where the second main power supply line 105b is disposed in each row.

Furthermore, as shown by arrows in FIG. 17, in both the sub-pixels P31 and P32 of the present embodiment, current flow between the source and the drain is in the negative direction of the X axis (a direction parallel to the boundary line BB). With this configuration, even if misalignment occurs, it is possible to prevent the transistor characteristics and the pixel circuit input/output characteristics from varying between the sub-pixels P31 and P32.

In other words, even in such a configuration of the present variation, the driving transistor Trda of the sub-pixel P31 and the driving transistor Trdb of the sub-pixel P32 are oriented in the same direction, and thus the same advantageous effects as those of the above embodiment can be obtained. Specifically, in the present variation, the driving transistor Trda of the sub-pixel P31 and the driving transistor Trdb of the sub-pixel P32 are oriented parallel to the boundary line BB between the sub-pixels P31 and P32.

### 8. Applications

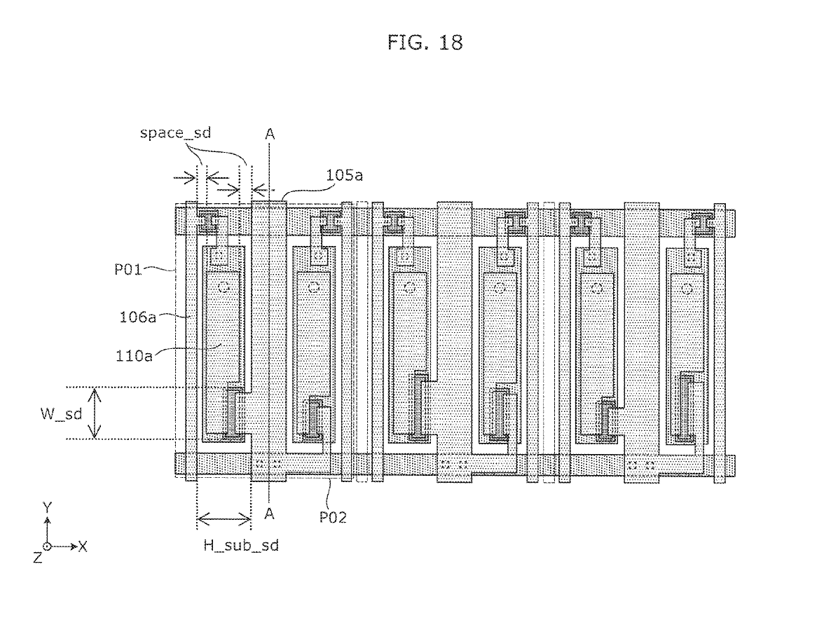

Conditions of organic EL panels suitable for use in applying the layouts of the above embodiment and Variations 1 to 3 will be described with reference to FIG. 18 to FIG. 21. FIG. 18 to FIG. 21 are layout diagrams illustrating examples of the applications of the embodiment and Variations 1 to 3.

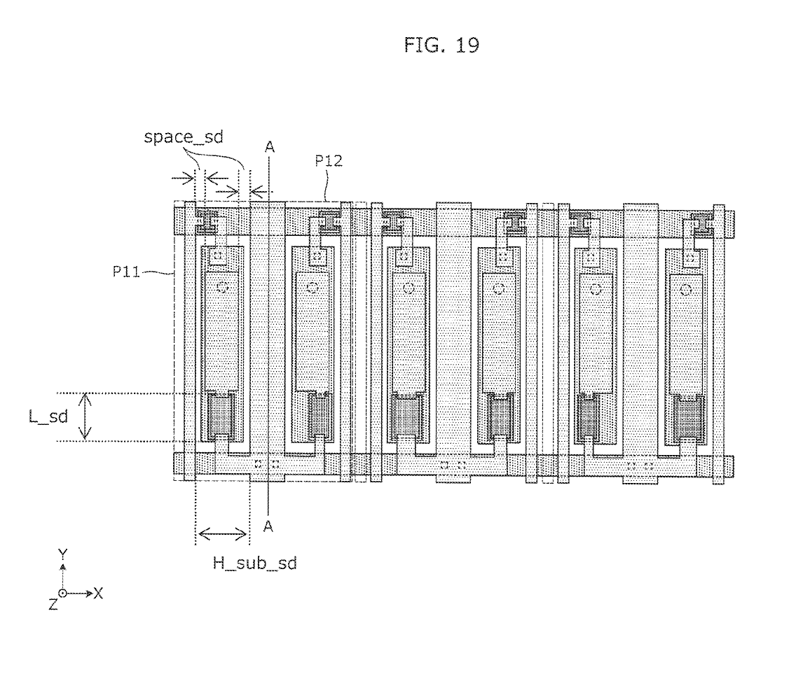

FIG. 18 and FIG. 19 are each a layout diagram illustrating a pixel layout in which two sub-pixels adjacent to each other in the row direction are paired.

In the layout shown in FIG. 18, the direction of current flow between the source and the drain indicated by arrows is perpendicular to the boundary line AA. The layout shown in FIG. 18 is applicable when the following formula (3) holds.

W_sd>H_sub_sd−space_sd×2 Formula (3)

W_sd is the gate width of the driving transistor. H_sub_sd is the distance (the distance in the X axis direction) between the data signal line 106a and the first main power supply line 105a. space_sd is the distance for isolating lines in the same layer. In FIG. 18, the distance “space_sd” corresponds to the distance between the data signal line 106a and the metal layer 110a in the X axis direction and the distance between the metal layer 110a and the first main power supply line 105a in the X axis direction.

In other words, it is preferable to apply the layout shown in FIG. 18 when the width “W_sd” of the driving transistor is greater than a distance obtained by subtracting twice a distance “space_sd” for isolating lines in the same layer from the distance “H_sub_sd” between a power supply line and a data signal line.

In the layout shown in FIG. 19, the direction of current flow between the source and the drain indicated by arrows is parallel to the boundary line AA. It is preferable to apply the layout shown in FIG. 19 when the following formula (4) holds.

L_sd>H_sub_sd−space_sd×2 Formula (4)

L_sd is the gate length of the driving transistor. In other words, it is preferable to apply the layout shown in FIG. 19 when the length “L_sd” of the driving transistor is greater than a distance obtained by subtracting twice a distance “space_sd” for isolating lines in the same layer from a distance “H_sub_sd” between a power supply line and a data signal line.

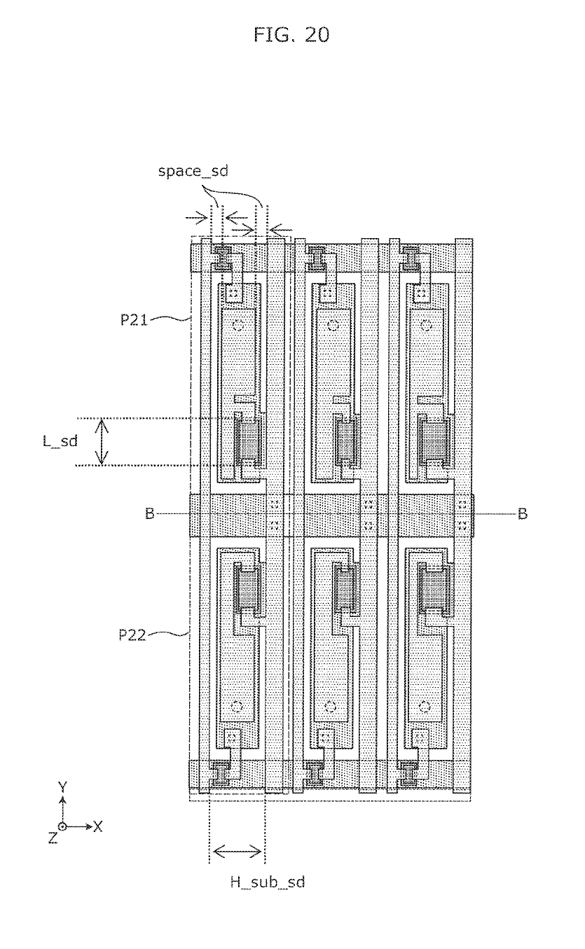

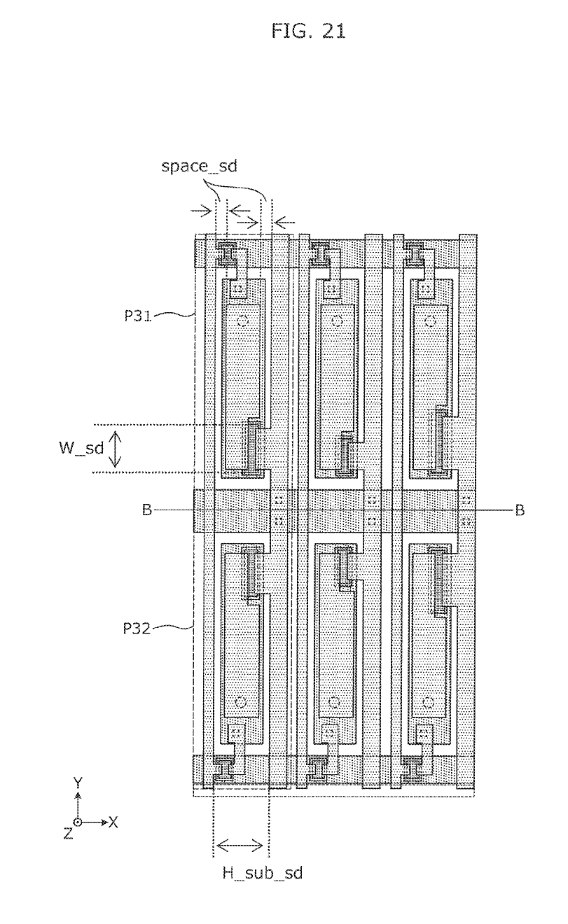

FIG. 20 and FIG. 21 are each a layout diagram illustrating a pixel layout in which two sub-pixels adjacent to each other in the column direction are paired.

In the layout shown in FIG. 20, the direction of current flow between the source and the drain indicated by arrows is perpendicular to the boundary line BB. It is preferable to apply the layout shown in FIG. 20 when the following formula (5) holds.

L_sd>H_sub_sd−space_sd×2 Formula (5)

In other words, it is possible to apply the layout shown in FIG. 20 when the length “L_sd” of the driving transistor is greater than a distance obtained by subtracting twice a distance “space_sd” for isolating lines in the same layer from a distance “H_sub_sd” between a power supply line and a data signal line.

In the layout shown in FIG. 21, the direction of current flow between the source and the drain indicated by arrows is parallel to the boundary line BB. It is preferable to apply the layout shown in FIG. 21 when the following formula (6) holds.

W_sd>H_sub_sd−space_sd×2 Formula (6)

In other words, it is preferable to apply the layout shown in FIG. 18 when the width “W_sd” of the driving transistor is greater than a distance obtained by subtracting twice a distance “space_sd” for isolating lines in the same layer from a distance “H_sub_sd” between a power supply line and a data signal line.

It is possible to choose the layout to be applied from among the above-mentioned layouts shown in FIG. 18 to FIG. 21 based on the gate length and gate width of the driving transistor. The conditions mentioned above are represented by simple formulae, and therefore it is easy to determine an applicable layout.

### Other Embodiments

The embodiment and Variations 1 and 2 have been described as examples of the technique disclosed in the present application. However, the technique according to the present disclosure is not limited to these examples, and is also applicable to embodiments with appropriate modification, replacement, addition, omission, etc. Furthermore, the components described in the above embodiment and Variations 1 to 3 can be combined to create a new embodiment.

For example, in the above embodiment and Variations 1 to 3, the case where a main power supply line is disposed on a boundary line has been described. However, there is no need to dispose the main power supply line such that the boundary line passes through the center of the main power supply line. It is only necessary that the main power supply line be disposed in a region including the boundary line.

Furthermore, in the above embodiment and Variations 1 to 3, the application to organic EL displays has been described, but the present disclosure is not limited to this. The present disclosure is also applicable to display devices in which each pixel includes a driving transistor, such as plasma displays and liquid crystal televisions.

Furthermore, in the above embodiment and Variations 1 to 3, each pixel includes sub-pixels corresponding to red, green, and green colors, but the configuration of the pixel is not limited to this. For example, the pixel may include a sub-pixel that emits white (W) light in addition to these three color sub-pixels. Furthermore, the arrangement of sub-pixels in a pixel is not particularly limited, and the sub-pixels in each pixel may be arranged such that sub-pixels of the same color are aligned in the column direction or may be arranged such that sub-pixels of the same color are aligned in the row direction. Alternatively, pixels may be arranged, for example, in a PenTile matrix in which sub-pixels of different colors are aligned in the column direction or the row direction.

Furthermore, in the above embodiment and Variations 1 to 3, the case where a first pixel and a second pixel arranged adjacent to each other are both sub-pixels in one pixel is described, but the configuration of the first pixel and the second pixel is not limited to this. For example, there may be a case where one of the first pixel and the second pixel is a sub-pixel in one pixel and the other is a sub-pixel in another pixel adjacent to the one pixel. Furthermore, the first pixel and the second pixel may be sub-pixels that emit light of the same color (such as white), for example.

The embodiments described above are intended to illustrate examples of the technique according to the present disclosure. The accompanying drawings and detailed description are provided for that purpose.

Thus, the components illustrated in the accompanying drawings or described in the detailed description may include not only components that are essential for solving the problems but also components that are not essential for solving the problems to Illustrate the above technique. Therefore, the components that are illustrated in the accompanying drawings or described in the detailed description but are not essential should not be considered as being essential based only on the fact that they appear in the accompanying drawings or the detailed description.

In addition, the embodiments described above are intended to illustrate the technique according to the present disclosure, and thus various modifications, replacements, additions, omissions, etc. may be made within the scope of claims and the equivalents thereof.

### INDUSTRIAL APPLICABILITY

The present disclosure is applicable to display devices capable of increasing the degree of integration and reducing variations in the transistor characteristics between sub-pixels. Specifically, the present disclosure is applicable to display devices such as organic EL displays, liquid crystal displays, and plasma displays.

### REFERENCE SIGNS LIST

1 organic EL display
10 organic EL panel
20 data line driving circuit
30 scanning line driving circuit
40 TCON
100 glass substrate
101, 101a, 101b, 101c, 101e, 101f gate metal layer
102, 102a, 102b, 102c, 102d semiconductor layer
103, 103a, 103b drain metal layer
104, 104a, 104b source metal layer
105 power supply line
105a first main power supply line
105b second main power supply line
105c first sub power supply line
105d second sub power supply line
106, 106a, 106b, DR, DR1 data signal line
106c first sub data line
106d second sub data line
107 gate insulating film
108 channel protection film
109d, 109s ohmic contact layer
110a, 110b, 111a, 111b metal layer
110c first sub source line
110d second sub source line
120a, 120b, 121a, 121b contact
130, 131 region
200 lens
Cs capacitor
Cgs, Cgd, Cgs0, Cgd0, Cgs1, Cgd1, Cgs2, Cgd2 parasitic capacitance
P pixel
P01, P02, P11, P21, P22, P23, P24, P25, P26, P31, P32, P101, P201, P202, PR, PG, PB sub-pixel
Trd, Trda, Trdb driving transistor
Trs, Trsa, Trsb switching transistor
Scan, Scan1 scanning signal line
VEL, VTFT power supply voltage

1. A display device comprising:
a first pixel and a second pixel arranged adjacent to each other and each including a driving transistor, and
a power supply line for supplying a power supply voltage to the driving transistor of the first pixel and the driving transistor of the second pixel, the power supply line being disposed at a boundary between the first pixel and the second pixel,
wherein the driving transistor of the first pixel and the driving transistor of the second pixel are oriented in a same direction.

2. The display device according to claim 1,
wherein the driving transistor of the first pixel and the driving transistor of the second pixel are oriented parallel to a line of the boundary between the first pixel and the second pixel.

3. The display device according to claim 2,
wherein in each of the first pixel and the second pixel,
a width of the driving transistor including a source metal layer and a drain metal layer is greater than a distance obtained by subtracting twice a distance for isolating lines in a same layer from a distance between the power supply line disposed between the first pixel and the second pixel and a data signal line for supplying a voltage corresponding to a gray scale level to a gate electrode of the driving transistor.

4. The display device according to claim 1,
wherein the driving transistor of the first pixel and the driving transistor of the second pixel are oriented perpendicularly to a line of the boundary between the first pixel and the second pixel.

5. The display device according to claim 4,
wherein in each of the first pixel and the second pixel,
a length of the driving transistor including a source metal layer and a drain metal layer is greater than a distance obtained by subtracting twice a distance for isolating lines in a same layer from a distance between the power supply line disposed between the first pixel and the second pixel and a data signal line for supplying a voltage corresponding to a gray scale level to a gate electrode of the driving transistor.

6. The display device according to claim 1,
wherein the first pixel and the second pixel are adjacent to each other in a column direction of a display panel including the first pixel and the second pixel.

7. The display device according to claim 1,
wherein the first pixel and the second pixel are adjacent to each other in a row direction of a display panel including the first pixel and the second pixel.

8. The display device according to claim 1,
wherein in a plan view of each of the first pixel and the second pixel, a gate metal layer, a source metal layer, and a drain metal layer of the driving transistor are arranged to partially or completely overlap one another.

9. The display device according to claim 1,
wherein the driving transistor has one of a lightly doped drain structure and an offset gate structure.

10. The display device according to claim 1,
wherein the driving transistor has one of a channel etching stopper structure and a back channel etching structure.

11. The display device according to claim 1,
wherein the first pixel and the second pixel each further include: a light-emitting element that emits light depending on a driving current supplied from the driving transistor; and a capacitor connected between a gate and a source of the driving transistor, and
the driving transistor is an N-type transistor, a source electrode of the driving transistor and an anode electrode of the light-emitting element are connected, and, during bootstrapping, a voltage accumulated in the capacitor varies depending on a parasitic capacitance formed between the gate and the source of the driving transistor and a parasitic capacitance formed between the gate and a drain of the driving transistor.
